(19) United States
(12) Patent Application Publication
(10) Pub. No.: US 2025/0212629 A1
(43) Pub. Date: Jun. 26, 2025

(54) DISPLAY SUBSTRATE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Wenzhe CAI, Beijing (CN); Qiwei WANG, Beijing (CN); Fan HE, Beijing (CN); Jun YAN, Beijing (CN); Kemeng TONG, Beijing (CN); Xiangdan DONG, Beijing (CN)

(21) Appl. No.: 18/851,084

(22) PCT Filed: Nov. 16, 2023
(86) PCT No.: PCT/CN2023/132047

§ 371 Date: Sep. 26, 2024

(30) Foreign Application Priority Data
Dec. 8, 2022 (CN) 202211582379.2

(51) Int. Cl. H10K 59/131; H10K 102/00

(52) U.S. Cl. CPC H10K 59/131; H10K 2102/341

(57) ABSTRACT

A display substrate and a display device. The display substrate comprises: a display area and a bezel area located around the display area, wherein the display area comprises at least one corner area, the bezel area comprises at least one corner area; a plurality of sub-pixels and a plurality of data lines located in the display area, wherein at least some of the plurality of sub-pixels are located in the at least one corner area of the display area and are arranged in a stepped mode, the plurality of data lines comprise a plurality of first data lines, and the plurality of first data lines are electrically connected to the at least some sub-pixels located in the at least one corner area of the display area and are configured to provide a data signal to the at least some sub pixels; and a plurality of first electrostatic discharge circuits located in the at least one corner area of the bezel area, wherein the plurality of first electrostatic discharge circuits are respectively electrically connected to the plurality of first data lines and are configured to discharge the static electricity in the plurality of first data lines.

### CROSS-REFERENCE TO RELATED APPLICATIONS

The present application is a U.S. National Phase Entry of International Application No. PCT/CN2023/132047 having an international filing date of Nov. 16, 2023, which claims the priority to Chinese Patent Application No. 202211582379.2, filed to the CNIPA on Dec. 8, 2022 and entitled “DISPLAY SUBSTRATE AND DISPLAY DEVICE”. The above-identified applications are incorporated into the present application by reference.

### TECHNICAL FIELD

Embodiments of the present disclosure relate to, but are not limited to, the field of display technologies, in particular to a display substrate and a display device.

### BACKGROUND

An Organic Light Emitting Diode (OLED) and a Quantum dot Light Emitting Diode (QLED) are active light emitting display devices and have advantages of self-luminescence, a wide viewing angle, a high contrast ratio, low power consumption, an extremely high response speed, lightness and thinness, bendability, and a low cost, etc.

### SUMMARY

The following is a summary of subject matters described herein in detail. This summary is not intended to limit the protection scope of claims.

At least one embodiment of the present disclosure provides a display substrate and a display device.

In a first aspect, an embodiment of the present disclosure provides a display substrate, including: a display region and a bezel region located around the display region, the display region including at least one corner region, the bezel region including at least one corner region, and the at least one corner region of the display region corresponding to the at least one corner region of the bezel region;

a plurality of sub-pixels and a plurality of data lines located in the display region, at least part of the plurality of sub-pixels being located in the at least one corner region of the display region and arranged in a stepped shape, the plurality of data lines including a plurality of first data lines which are electrically connected to at least part of the sub-pixels located in the at least one corner region of the display region and configured to provide data signals to the at least part of the sub-pixels; and a plurality of first electrostatic discharge circuits located in the at least one corner region of the bezel region, the plurality of first electrostatic discharge circuits being electrically connected to the plurality of first data lines, respectively, and configured to discharge static electricity in the plurality of first data lines.

In some exemplary implementations, the bezel region further includes a first bezel region and a second bezel region located on two sides of the display region in a second direction, and a third bezel region and a fourth bezel region located on two sides of the display region in a first direction; the at least one corner region of the bezel region includes a first corner region connecting the first bezel region and the third bezel region, a second corner region connecting the third bezel region and the second bezel region, a third corner region connecting the second bezel region and the fourth bezel region, and a fourth corner region connecting the fourth bezel region and the first bezel region.

The plurality of first electrostatic discharge circuits are provided in the second corner region and the third corner region; or, the plurality of first electrostatic discharge circuits are provided in the first corner region and the fourth corner region.

In some exemplary implementations, the plurality of sub-pixels include a plurality of sub-pixel columns, and the plurality of sub-pixel columns include a plurality of first sub-pixel columns located in the at least one corner region of the display region.

In some exemplary implementations, a boundary of the at least one corner region of the display region has a stepped shape, the plurality of first sub-pixel columns are arranged in a stepped shape, the plurality of first electrostatic discharge circuits are arranged in a stepped shape, the plurality of first electrostatic discharge circuits correspond to the plurality of first sub-pixel columns in a one-to-one correspondence, and a step position of any one of the first electrostatic discharge circuits is consistent with a step position of a corresponding first sub-pixel column.

In some exemplary implementations, the boundary of the at least one corner region of the display region is arc-shaped, the plurality of first electrostatic discharge circuits are arranged in an array and located on a side of the at least one corner region close to the display region, and the plurality of first electrostatic discharge circuits correspond to the plurality of first sub-pixel columns in a one-to-one correspondence.

In some exemplary implementations, a plurality of first electrostatic discharge circuits located in a same column includes a plurality of first electrostatic discharge sub-circuits and a plurality of second electrostatic discharge sub-circuits, and the first electrostatic discharge sub-circuits and the second electrostatic discharge sub-circuits are alternately arranged in the second direction.

In some exemplary implementations, an arrangement direction of a plurality of discharge transistors included in the first electrostatic discharge sub-circuits and an arrangement direction of a plurality of discharge transistors included in the second electrostatic discharge sub-circuits are opposite to each other.

In some exemplary implementations, the plurality of sub-pixel columns further includes a plurality of second sub-pixel columns, the plurality of data lines further include a plurality of second data lines providing data signals to sub-pixels in the plurality of second sub-pixel columns respectively, the first bezel region or the second bezel region is further provided with a plurality of second electrostatic discharge circuits, herein the plurality of second electrostatic discharge circuits are electrically connected to the plurality of second data lines respectively and are configured to discharge static electricity in the plurality of second data lines, and the plurality of second electrostatic discharge circuits correspond to the plurality of second sub-pixel columns in a one-to-one correspondence.

In some exemplary implementations, the display substrate further includes a plurality of drive signal lines and a plurality of third electrostatic discharge circuits located in the bezel region; herein the plurality of third electrostatic discharge circuits are electrically connected to the plurality of drive signal lines respectively and are configured to discharge static electricity in the drive signal lines, the plurality of drive signal lines are located in the third bezel region and the fourth bezel region, the drive signal lines located in the third bezel region extend to the first corner region and the second corner region, and the drive signal lines located in the fourth bezel region extend to the third corner region and the fourth corner region; and the third electrostatic discharge circuits are provided in the first corner region and the fourth corner region, or the third electrostatic discharge circuits are provided in the second corner region and the third corner region.

In some exemplary implementations, the display substrate further includes a third power supply line and a fourth power supply line located in the bezel region; herein the plurality of third electrostatic discharge circuits and the plurality of first electrostatic discharge circuits are all electrically connected to the third power supply line and the fourth power supply line; herein the third power supply line and the fourth power supply line are located in the third bezel region and the fourth bezel region, a third power supply line and a fourth power supply line located in the third bezel region extend to the first corner region and the second corner region, and a third power supply line and a fourth power supply line located in the fourth bezel region extend to the third corner region and the fourth corner region.

In some exemplary implementations, the display substrate further includes a plurality of drive circuits located in the bezel region, which are located in the third bezel region, the fourth bezel region, the first corner region, the second corner region, the third corner region, and the fourth corner region.

The plurality of drive circuits are electrically connected to the plurality of drive signal lines, the third power supply line, and the fourth power supply line.

In some exemplary implementations, the display substrate further includes a plurality of effective drive circuit regions, a plurality of first virtual drive circuit regions and a plurality of second virtual drive circuit regions located in the bezel region, herein the plurality of effective drive circuit regions are arranged along an extending direction of the bezel region, the plurality of first virtual drive circuit regions and the plurality of second virtual drive circuit regions are disposed alternately between the plurality of effective drive circuit regions, the plurality of effective drive circuit regions are respectively provided with a plurality of drive circuits, the plurality of first virtual drive circuit regions are respectively provided with a plurality of virtual drive circuits, the plurality of second virtual drive circuit regions are located in the corner region, and the plurality of first electrostatic discharge circuits are provided in the plurality of second virtual drive circuit regions.

In some exemplary implementations, the display substrate further includes a third power supply line, a fourth power supply line, a plurality of drive signal lines, and a plurality of third electrostatic discharge circuits located in the bezel region; herein the plurality of third electrostatic discharge circuits are electrically connected to the plurality of drive signal lines respectively, and are configured to discharge static electricity in the plurality of drive signal lines; herein the plurality of third electrostatic discharge circuits and the plurality of first electrostatic discharge circuits are all electrically connected to the third power supply line and the fourth power supply line.

In some exemplary implementations, in a direction perpendicular to a plane where the display substrate is located, the display substrate includes a base substrate and a semiconductor layer, a first conductive layer, a second conductive layer, a third conductive layer and a fourth conductive layer stacked sequentially on the base substrate, herein the first conductive layer includes a plurality of first transfer connection electrodes, the second conductive layer includes a plurality of second transfer connection electrodes, the plurality of first transfer connection electrodes and the plurality of second transfer connection electrodes are alternately arranged in a first direction, with one ends being electrically connected to the plurality of first data lines respectively, and the other ends being electrically connected to the plurality of first electrostatic discharge circuits respectively.

In some exemplary implementations, the display substrate further includes a plurality of first connection lines;
a plurality of first signal lines located in the display region; herein in a direction parallel to the plane where the display substrate is located, the plurality of first signal lines extend in the first direction and are arranged in a second direction, the plurality of data lines are arranged in the first direction and extend in the second direction; and herein the plurality of first signal lines and the plurality of data lines are arranged in different layers; and
a plurality of drive circuits, a plurality of third electrostatic discharge circuits and a plurality of drive signal lines located in the bezel region; herein one ends of the plurality of first connection lines are electrically connected to the plurality of first signal lines respectively, and the other ends of the plurality of first connection lines are electrically connected to the plurality of drive circuits and the plurality of drive signal lines respectively.

In some exemplary implementations, the plurality of first electrostatic discharge circuits are arranged in an array, at least part of the first transfer connection electrodes and the second transfer connection electrodes are in an arc-shaped structure, the first electrostatic discharge circuits are electrically connected to one of the first data lines through an arc-shaped first transfer connection electrode or second transfer connection electrode, and the plurality of drive signal lines are provided in the third conductive layer.

The first connection lines and at least part of the first signal lines are provided in the third conductive layer, and the plurality of data lines are provided in the fourth conductive layer; or, the first connection lines and at least part of the first signal lines are provided in the fourth conductive layer, and the plurality of data lines are provided in the third conductive layer.

In some exemplary implementations, the display substrate further includes a plurality of third power supply lines and a plurality of fourth power supply lines located in the bezel region; and a plurality of third power supply connection lines and a plurality of fourth power supply connection lines located in at least one corner region of the bezel region, herein one ends of the plurality of third power supply connection lines are electrically connected to the plurality of third power supply lines respectively, and the other ends of the plurality of third power supply connection lines are electrically connected to the plurality of third electrostatic discharge circuits and the plurality of first electrostatic discharge circuits respectively; and one ends of the plurality of fourth power supply connection lines are electrically connected to the plurality of fourth power supply lines respectively, and the other ends of the plurality of fourth power supply connection lines are electrically connected to the plurality of third electrostatic discharge circuits and the plurality of first electrostatic discharge circuits respectively.

The plurality of third electrostatic discharge circuits, the plurality of third power supply connection lines, and the plurality of fourth power supply connection lines are arranged in a stepped shape, and the third power supply connection lines and the fourth power supply connection lines are in a shape of a bending line extending in the first direction.

In some exemplary implementations, the plurality of third power supply lines, the plurality of fourth power supply lines and the plurality of fourth power supply connection lines are provided in the third conductive layer, the plurality of third power supply connection lines include a first power supply connection structure and a plurality of second power supply connection structures, the first power supply connection structure is provided in the first conductive layer and is electrically connected to one of the third power supply lines, at least part of the third electrostatic discharge circuits, and a plurality of first electrostatic discharge circuits in a first row; a second power supply connection structure includes a first power supply connection substructure and a second power supply connection substructure, herein the first power supply connection substructure is in a shape of a bending line and is provided in the first conductive layer, and is electrically connected to the plurality of third electrostatic discharge sub-circuits, the plurality of third power supply lines and the second power supply connection substructure, and herein the second power supply connection substructure is provided in the third conductive layer and is electrically connected to the first power supply connection substructure and the plurality of first electrostatic discharge circuits.

In some exemplary implementations, the plurality of first electrostatic discharge circuits are arranged in a stepped shape, the bezel region further includes a plurality of third transfer connection electrodes arranged in a stepped shape, herein the plurality of first transfer connection electrodes and the plurality of second transfer connection electrodes are respectively electrically connected to the plurality of first electrostatic discharge circuits through the plurality of third transfer connection electrodes.

The plurality of third transfer connection electrodes are provided in the third conductive layer, the plurality of data lines are provided in the fourth conductive layer, and the plurality of first signal lines are provided in one or more layers from the first conductive layer to the third conductive layer.

In some exemplary implementations, the display substrate further includes: a third power supply line and a fourth power supply line located in the bezel region; and a plurality of third power supply connection lines, a plurality of fourth power supply connection lines, a third power supply connection electrode and a fourth power supply connection electrode, which are located in at least one corner region of the bezel region.

One ends of the plurality of third power supply connection lines are electrically connected to the plurality of third power supply lines respectively, and the other ends of the plurality of third power supply connection lines are electrically connected to the plurality of third electrostatic discharge circuits respectively; one of the third power supply connection lines is electrically connected to the third power supply connection electrode, and one of the fourth power supply connection lines is electrically connected to the fourth power supply connection electrode.

The third power supply connection electrode is electrically connected to one of the third power supply connection lines and one ends of the plurality of first electrostatic discharge circuits, and the fourth power supply connection electrode is electrically connected to one f of the fourth power supply connection lines and the other ends of the plurality of first electrostatic discharge circuits.

In some exemplary implementations, the plurality of third electrostatic discharge circuits, the plurality of third power supply connection lines, and the plurality of fourth power supply connection lines are arranged in a stepped shape, the third power supply connection lines and the fourth power supply connection lines are in a structure of a bending line extending in the first direction, the third power supply connection electrode and the fourth power supply connection electrode are in a stepped blending line structure with extending directions being consistent with an extending direction of a corresponding corner region in the bezel region.

The third power supply line, the fourth power supply line and the fourth power supply connection lines are provided in the third conductive layer, and the third power supply connection lines, the third power supply connection electrode and the fourth power supply connection electrode are provided in the first conductive layer.

In a second aspect, an embodiment of the present disclosure provides a display device including the display substrate as described above, and light emitting elements disposed in the display region of the display substrate, herein the light emitting elements are arranged in an array.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, but are only intended to schematically describe contents of the present disclosure.

FIG. 1 is a schematic diagram of a structure of a display device.

FIG. 2 is a schematic diagram of a structure of a display device.

FIG. 3 is a schematic diagram of a partial sectional structure of a display region of a display substrate.

FIG. 4 is an equivalent circuit diagram of a pixel circuit.

FIG. 5a is a schematic diagram of a structure of a display device according to an embodiment of the present disclosure.

FIG. 5b is a schematic diagram of a structure of a display panel according to an embodiment of the present disclosure.

FIG. 6 is a schematic partial enlarged view of M1 in FIG. 5a.

FIG. 7 is a schematic partial enlarged view of a corner region of a bezel region according to an exemplary embodiment of the present disclosure.

FIG. 8 is a schematic partial enlarged view of a second corner region according to at least one exemplary embodiment of the present disclosure.

FIG. 9 is an equivalent circuit diagram of an electrostatic discharge circuit according to at least one exemplary embodiment of the present disclosure.

FIG. 10A is a schematic diagram of a structure of an electrostatic discharge circuit according to at least one exemplary embodiment of the present disclosure.

FIG. 10B is a schematic diagram of a structure of the electrostatic discharge circuit after a second conductive layer is formed in FIG. 10A.

FIG. 10C is a schematic diagram of a structure of the electrostatic discharge circuit after a third insulation layer is formed in FIG. 10A.

FIG. 11A is a schematic diagram of a structure of an electrostatic discharge circuit according to at least one exemplary embodiment of the present disclosure.

FIG. 11B is a schematic diagram of a structure of the electrostatic discharge circuit after a second conductive layer is formed in FIG. 11A.

FIG. 11C is a schematic diagram of a structure of the electrostatic discharge circuit after a third insulation layer is formed in FIG. 11A.

FIG. 11D is a schematic diagram of a structure of a plurality of first electrostatic discharge circuits ST11 corresponding to a step position in FIG. 6.

FIG. 12 is a schematic partial enlarged view of a first corner region according to at least one exemplary embodiment of the present disclosure.

FIG. 13A is a schematic diagram of a structure of an electrostatic discharge circuit according to at least one exemplary embodiment of the present disclosure.

FIG. 13B is a schematic diagram of a structure of the electrostatic discharge circuit after a second conductive layer is formed in FIG. 13A.

FIG. 13C is a schematic diagram of a structure of the electrostatic discharge circuit after a third insulation layer is formed in FIG. 13A.

FIG. 14 is a schematic diagram of a structure of a display device according to at least one exemplary embodiment of the present disclosure.

FIG. 15 is a schematic diagram of a display device according to at least one embodiment of the present disclosure.

### DETAILED DESCRIPTION

Hereinafter embodiments of the present disclosure will be described in detail with reference to the accompanying drawings. Implementation modes may be implemented in a plurality of different forms. Those of ordinary skills in the art may easily understand such a fact that implementations and contents may be transformed into other forms without departing from the purpose and scope of embodiments of the present disclosure. Therefore, the embodiments of the present disclosure should not be explained as being limited to the contents recorded in the following implementations only. The embodiments in the present application and features in the embodiments may be combined with each other randomly if there is no conflict.

In the drawings, a size of one or more constituent elements, a thickness of a layer, or a region is sometimes exaggerated for clarity. Therefore, an implementation of the embodiments of the present disclosure is not necessarily limited to the size, and a shape and a size of one or more components in the drawings do not reflect an actual scale. In addition, the accompanying drawings schematically illustrate ideal examples, and an implementation of the embodiments of the present disclosure is not limited to shapes, numerical values, or the like shown in the drawings.

Ordinal numerals “first”, “second”, “third”, etc., in the specification are set not to form limits in quantities but only to avoid confusion between composition elements. “A plurality of” in the embodiments of the present disclosure denotes a quantity of two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, a transistor refers to an element which at least includes three terminals, i.e., a gate (gate electrode), a drain, and a source. The transistor has a channel region between the drain electrode (drain electrode terminal, drain electrode region, or drain electrode) and the source electrode (source electrode terminal, source electrode region, or source electrode), and a current can flow through the drain electrode, the channel region, and the source electrode. In the specification, the channel region refers to a region through which a current mainly flows.

In the specification, a first electrode may be a drain electrode and a second electrode may be a source electrode, or, a first electrode may be a source electrode and a second electrode may be a drain electrode. In addition, the gate may also be referred to as a control electrode. In a case that transistors with opposite polarities are used, or in a case that a direction of a current is changed during operation of a circuit, or the like, functions of the “source electrode” and the “drain electrode” are sometimes interchangeable. Therefore, the “source electrode” and the “drain electrode” are interchangeable in the specification. In implementations of the present disclosure, the gate may be referred to as a control electrode.

In the specification, “electrical connection” includes connection of composition elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with a plurality of functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In this specification, a circle, oval, triangle, rectangle, trapezoid, pentagon or hexagon, etc. is not strictly speaking, but may be an approximate circle, oval, triangle, rectangle, trapezoid, pentagon or hexagon, etc. Some small deformations due to tolerances may exist, for example, guide angles, curved edges and deformations thereof may exist.

In the specification, “about” and “substantially” refer to that a boundary is not defined strictly and a case within a process and measurement error range is allowed. In the present disclosure, “substantially the same” refers to a case where numerical values differ by less than 10%.

In the present specification, “A extends along a B direction” means that A may include a main portion and a secondary portion connected to the main portion, the main portion is a line, a line segment, or a strip-shaped body, the main portion extends along the B direction, and a length of the main portion extending along the B direction is greater than a length of the secondary portion extending along another direction. “A extends in a B direction” in the present specification always means “a main portion of A extends in a B direction”.

“A and B are of a same layer structure” mentioned in the present specification means that A and B are formed simultaneously through a same patterning process. A “same layer” does not always mean that thicknesses of layers or heights of layers are the same in a section diagram. “An orthographic projection of A contains an orthographic projection of B” means that the orthographic projection of B falls within a range of the orthographic projection of A, or the orthographic projection of A covers the orthographic projection of B.

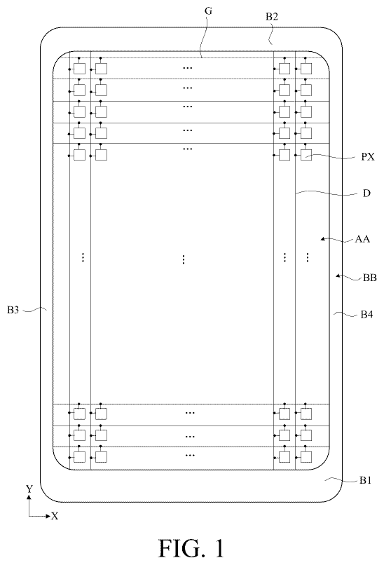

FIG. 1 is a schematic diagram of an appearance of a display device, which has a rectangular shape with rounded chamfers. The display device may include a display substrate. In some examples, the display substrate may be a closed polygon including linear edges, a circle or an ellipse including a curved edge, a semicircle or semi-ellipse including a linear edge and a curved edge, or the like. In some examples, when the base substrate has a linear edge, at least some corners of the base substrate may be curved. When the base substrate is in a shape of a rectangle, a portion at a position where adjacent linear edges intersect with each other may be replaced by a curve with a predetermined curvature. Herein, the curvature may be set according to different positions of the curve. For example, the curvature may be changed according to a starting position of the curve, a length of the curve, etc.

In some examples, as shown in FIG. 1, the display substrate may include a display region AA and a peripheral region BB located around the display region AA. In some examples, the display region AA may include a first edge (lower edge) and a second edge (upper edge) oppositely disposed in the second direction Y, and a third edge (left edge) and a fourth edge (right edge) oppositely disposed in the first direction X. Adjacent edges can be connected by an arcuate chamfer to form a quadrilateral shape with a rounded chamfer. In some examples, the peripheral region BB may include a first bezel (lower bezel) B1 and a second bezel (upper bezel) B2 oppositely disposed in the second direction Y, and a third bezel (left bezel) B3 and a fourth bezel (right bezel) B4 oppositely disposed in the first direction X. The first bezel B1 is in communication with the third bezel B3 and the fourth bezel B4, and the second bezel B2 is in communication with the third bezel B3 and the fourth bezel B4.

In some examples, as shown in FIG. 1, the display region AA at least include a plurality of sub-pixels PX, a plurality of gate lines G, and a plurality of data lines D. The plurality of gate lines G may extend in the first direction X, and the plurality of data lines D may extend in the second direction Y. Orthographic projections of the plurality of gate lines G on the base substrate and orthographic projections of the plurality of data lines D on the base substrate intersect to form a plurality of sub-pixel regions, and one of the sub-pixels PX is disposed in each sub-pixel region. The plurality of data lines D are electrically connected with a plurality of sub-pixels PX and may be configured to provide data signals to the plurality of sub-pixels PX. The plurality of gate lines G are electrically connected with the plurality of sub-pixels PX and may be configured to provide gate control signals to the plurality of sub-pixels PX. In some examples, the gate control signals may include a scan signal and a light emitting control signal.

In some examples, as shown in FIG. 1, the first direction X may be an extension direction of the gate lines G in the display region (row direction), and the second direction Y may be an extension direction of the data lines D in the display region (column direction). The first direction X and the second direction Y may be perpendicular to each other.

In some examples, a pixel unit of the display region AA may include three sub-pixels which are a red sub-pixel, a green sub-pixel, and a blue sub-pixel respectively. However, the present embodiment is not limited thereto. In some examples, one pixel unit may include four sub-pixels, and the four sub-pixels are a red sub-pixel, a green sub-pixel, a blue sub-pixel, and a white sub-pixel respectively.

In some examples, a shape of a sub-pixel may be a rectangle, a rhombus, a pentagon, or a hexagon. When one pixel unit includes three sub-pixels, the three sub-pixels may be arranged in parallel in a horizontal direction, in parallel in a vertical direction, or in a shape of Chinese character “ [symbol] ”. When one pixel unit includes four sub-pixels, the four sub-pixels may be arranged in parallel in a horizontal direction, in parallel in a vertical direction, or in a square. However, the present embodiment is not limited thereto.

In some examples, a sub-pixel may include a pixel circuit and a light emitting element electrically connected with the pixel circuit. The pixel circuit may include multiple transistors and at least one capacitor. For example, the pixel circuit may be of a 3T1C (i.e., three transistors and one capacitor) structure, a 7T1C (i.e., seven transistors and one capacitor) structure, a 5T1C (i.e., five transistors and one capacitor) structure, an 8T1C (eight transistors and one capacitor) structure, or an 8T2C (eight transistors and two capacitors) structure, or the like.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected to a corresponding pixel circuit. However, the present embodiment is not limited thereto.

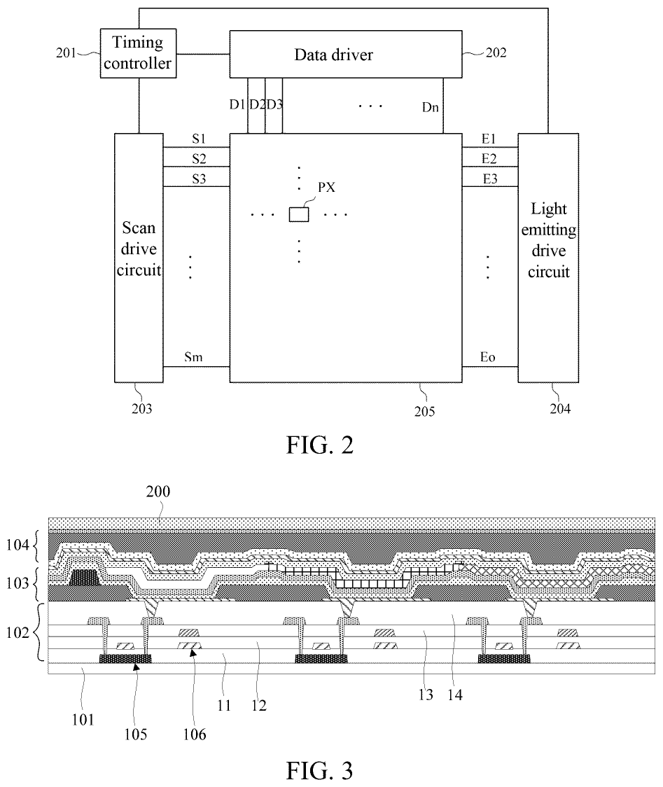

FIG. 2 is a schematic diagram of a structure of a display device. In some examples, as shown in FIG. 2, the display device may include a timing controller 201, a data driver 202, a scan drive circuit 203, a light emitting drive circuit 204 and a display substrate 205. In some examples, the display region of the display substrate 205 may include a plurality of sub-pixels PX arranged regularly. The scan drive circuit 203 may be configured to supply a scan signal to a sub-pixel PX along a scan line. The data driver 202 may be configured to supply a data voltage to a sub-pixel PX along a data line. The light emitting drive circuit 204 may be configured to supply a light emitting control signal to a sub-pixel PX along a light emitting control line. The timing controller 201 may be configured to control the scan drive circuit 203, the light emitting drive circuit 204 and the data driver 202.

In some examples, the timing controller 201 may provide a gray-scale value and a control signal suitable for a specification of the data driver 202 to the data driver 202; the timing controller 201 may provide a scan clock signal, a scan start signal, etc., suitable for a specification of the scan drive circuit 203 to the scan drive circuit 203; the timing controller 201 may provide a light-emitting clock signal, a light-emitting start signal, etc., suitable for a specification of the light-emitting drive circuit 204 to the light-emitting drive circuit 204. The data driver 202 may generate a data voltage, which will be provided to data lines D1 to Dn, using the gray-scale value and the control signal received from the timing controller 201. For example, the data driver 202 may sample the gray-scale value using the clock signal and apply the data voltage corresponding to the gray-scale value to the data lines D1 to Dn using a sub-pixel row as a unit. The scan circuit 203 may receive the scan clock signal, the scan start signal, etc., from the timing controller 201 to generate a scan signal to be provided to scan lines S1 to Sm. For example, the scan drive circuit 203 may sequentially provide scan signals with on-level pulses to scan lines. In some examples, the scan drive circuit 203 may include a shift register and may generate a scan signal by means of sequentially transmitting a scan start signal provided in a form of an on-level pulse to a next-stage circuit under control of a scan clock signal. The light emitting drive circuit 204 may receive the light emitting clock signal, the light emitting start signal, etc., from the timing controller 201 to generate a light emitting control signal to be provided to light emitting control lines E1 to Eo. For example, the light-emitting drive circuit 204 may provide sequentially light-emitting start signals with off-level pulses to the light-emitting control lines. The light-emitting drive circuit 204 may include a shift register, and generate a light-emitting control signal by means of sequentially transmitting a light-emitting start signal provided in a form of an off-level pulse to a next-stage circuit under control of a light-emitting clock signal. Herein, n, m, and o are all natural numbers.

In some examples, the scan drive circuit and the light emitting drive circuit may be directly disposed on the display substrate. For example, the scan drive circuit may be disposed at the third bezel of the display substrate, and the light emitting drive circuit may be disposed at the fourth bezel of the display substrate. Or, the third bezel and the fourth bezel of the display substrate may be both provided with the scan drive circuit and the light emitting drive circuit. In some examples, the scan drive circuit and the light emitting drive circuit may be formed together with the sub-pixels in a process of forming the sub-pixels.

In some examples, the data driver may be disposed on an independent chip or printed circuit board to be connected to the sub-pixel through the signal access pin on the display substrate. For example, the data driver may be formed and disposed at the first bezel of the display substrate using a chip on glass, a chip on plastics, a chip on film, etc., to be connected to the signal access pin. The timing controller may be arranged separately from or integrally with the data driver. However, the present embodiment is not limited thereto. In some examples, the data driver may be directly disposed on the display substrate.

FIG. 3 is a schematic diagram of a partial sectional structure of a display region of a display substrate. FIG. 3 illustrates structures of three sub-pixels of the display substrate. In some example, as shown in FIG. 3, in a direction perpendicular to the display substrate, the display substrate may include: a base substrate 101, and a circuit structure layer 102, a light emitting structure layer 103, an encapsulation layer 104 and an encapsulation cover plate 200 that are sequentially disposed on the base substrate 101. In some possible implementations, the display substrate may include another film layer, such as a post spacer, which is not limited in the present disclosure.

In some examples, the base substrate 101 may be a rigid underlay substrate, e.g., a glass underlay substrate. However, the present embodiment is not limited thereto. For example, the base substrate may be a flexible underlay substrate, e.g., prepared from an insulation material like a resin. In addition, the base substrate may be a single-layer structure or a multilayer structure. When the base substrate is a multilayer structure, an inorganic material such as silicon nitride, silicon oxide, and silicon oxynitride may be arranged between a plurality of layers as a single layer or multiple layers.

In some examples, the circuit structure layer 102 of each sub-pixel may include a plurality of transistors and a storage capacitor which form a pixel circuit. Illustration is made in FIG. 3 by taking each sub-pixel including one transistor and one storage capacitor as an example. In some possible implementations, the circuit structure layer 102 of each sub-pixel may include: an active layer disposed on the base substrate 101; a first insulation layer 11 covering the active layer; a first gate metal layer (including, for example, a gate electrode and a first capacitor electrode) disposed on the first insulation layer 11; a second insulation layer 12 covering the first gate metal layer; a second gate metal layer (e.g. including a second capacitor electrode) disposed on the second insulation layer 12; a third insulation layer 13 covering the second gate metal layer, herein the first insulation layer 11, the second insulation layer 12 and the third insulation layer 13 are provided with vias, and the vias expose the active layer; a first source-drain metal layer (including, for example, a source electrode and a drain electrode of a transistor) disposed on the third insulation layer 13, herein the source electrode and the drain electrode may be connected to the active layer through a via, respectively; and a first planarization 14 covering the aforementioned structure, herein the first planarization 14 is provided with a via, the via exposes the drain electrode. The active layer, the gate electrode, the source electrode, and the drain electrode may form the transistor 105, and the first capacitance electrode and the second capacitance electrode may form the storage capacitor 106.

In some examples, the light emitting structure layer 103 may include an anode layer, a pixel definition layer, an organic light emitting layer, and a cathode. The anode layer may include an anode of the light emitting element, the anode is disposed on the planarization layer and is connected with the drain electrode of the transistor of the pixel circuit through a via provided on the planarization layer; the pixel definition layer is disposed on the anode layer and the planarization layer, and a pixel opening is provided on the pixel definition layer and exposes the anode; the organic light emitting layer is at least partially disposed in the pixel opening and is connected with the anode; the cathode is disposed on the organic light emitting layer and is connected with the organic light emitting layer; and the organic light emitting layer emits light of a corresponding color under drive of the anode and the cathode.

In some examples, the encapsulation structure layer 104 may include a first encapsulation layer, a second encapsulation layer, and a third encapsulation layer that are stacked. The first encapsulation layer and the third encapsulation layer may adopt an inorganic material, and the second encapsulation layer may adopt an organic material. The second encapsulation layer is disposed between the first encapsulation layer and the third encapsulation layer, which can ensure that outside water vapor cannot enter the light emitting structure layer 103.

In some examples, the organic light emitting layer may at least include a hole injection layer, a hole transport layer, a light emitting layer and a hole block layer which are stacked on the anode. In some examples, the hole injection layers of all sub-pixels may be a common layer connected together; the hole transport layers of all sub-pixels may be a common layer connected together; the light emitting layers of close to sub-pixels may be slightly overlapped or isolated; and the hole block layers may be a common layer connected together. However, the present embodiment is not limited thereto.

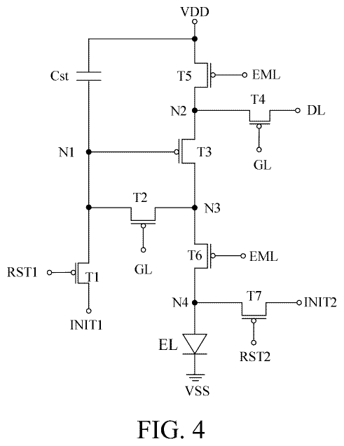

FIG. 4 is an equivalent circuit diagram of a pixel circuit. In some examples, as shown in FIG. 4, the pixel circuit of this example may include seven transistors (i.e. a first transistor T1 to a seventh transistor T7) and one storage capacitor Cst. A gate of the third transistor T3 is electrically connected with a first node N1, a first electrode of the third transistor T3 is electrically connected with a second node N2, and a second electrode of the third transistor T3 is electrically connected with the third node N3. The third transistor T3 may be referred to as a drive transistor. A gate of the fourth transistor T4 is electrically connected with the first scan line GL, a first electrode of the fourth transistor T4 is electrically connected with the data line DL, and a second electrode of the fourth transistor T4 is electrically connected with the first electrode of the third transistor T3. The fourth transistor T4 may be referred to as a data write transistor. A gate of the second transistor T2 is electrically connected with the first scan line GL, a first electrode of the second transistor T2 is electrically connected with the gate of the third transistor T3, and a second electrode of the second transistor T2 is electrically connected with the second electrode of the third transistor T3. The second transistor T2 may also be referred to as a threshold compensation transistor. A gate of the fifth transistor T5 is electrically connected with the light emitting control line EML, a first electrode of the fifth transistor T5 is electrically connected with the second power supply line VDD, and a second electrode of the fifth transistor T5 is electrically connected with the first electrode of the third transistor T3. A gate of the sixth transistor T6 is electrically connected with the light emitting control line EML, a first electrode of the sixth transistor T6 is electrically connected with the second electrode of the third transistor T3, and a second electrode of the sixth transistor T6 is electrically connected with an anode of the light emitting element EL. The fifth transistor T5 and the sixth transistor T6 may be referred to as light emitting control transistors. The first transistor T1 is electrically connected with the gate of the third transistor T3 and configured to reset the gate of the third transistor T3, and the seventh transistor T7 is electrically connected with the anode of the light emitting element EL and configured to reset the anode of the light emitting element EL. A gate of the first transistor T1 is electrically connected with a second scan line RST1, a first electrode of the first transistor T1 is electrically connected with a first initial signal line INIT1, and a second electrode of the first transistor T1 is electrically connected with the gate of the third transistor T3. A gate of the seventh transistor T7 is electrically connected with the third scan line RST2, a first electrode of the seventh transistor T7 is electrically connected with the second initial signal line INIT2, and a second electrode of the seventh transistor T7 is electrically connected with the anode of the light emitting element EL. The first transistor T1 and the seventh transistor T7 may also be referred to as reset control transistors. A first capacitor plate of the storage capacitor Cst is electrically connected with the gate of the third transistor T3, and a second capacitor plate of the storage capacitor Cst is electrically connected with the second power supply line VDD.

In this example, the first node N1 is a connection point for the storage capacitor Cst, the first transistor T1, the third transistor T3 and the second transistor T2, the second node N2 is a connection point for the fifth transistor T5, the fourth transistor T4, and the third transistor T3, the third node N3 is a connection point for the third transistor T3, the second transistor T2, and the sixth transistor T6, the fourth node N4 is a connection point for the sixth transistor T6, the seventh transistor T7, and the light emitting element EL.

In some examples, the first transistor T1 to the seventh transistor T7 may be P-type transistors or may be N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In some examples, the second power supply line VDD may be configured to provide a constant second voltage signal for a pixel circuit, the first power supply line VSS may be configured to provide a constant first voltage signal to a pixel circuit, herein the second voltage signal may be greater than the first voltage signal. The first scan line GL may be configured to provide a scan signal SCAN to the pixel circuit, the data line DL may be configured to provide a data signal DATA to the pixel circuit, the light emitting control line EML may be configured to provide a light emitting control signal EM to the pixel circuit, the second scan line RST1 may be configured to provide a first reset control signal RESET1 to the pixel circuit, and the third scan line RST2 may be configured to provide a second reset control signal RESET2 to the pixel circuit. In some examples, a second scan line RST1 electrically connected with an n-th row of pixel circuits may be electrically connected with a first scan line GL of an (n−1)-th row of pixel circuits, so as to be inputted with a scan signal SCAN(n−1). That is, a first reset control signal RESET1(n) is the same as the scan signal SCAN(n−1). A third scan line RST2 of the n-th row of pixel circuits may be electrically connected with a first scan line GL of the n-th row of pixel circuits, so as to be inputted with a scan signal SCAN(n). That is, a second reset control signal RESET2(n) may be the same as the scan signal SCAN(n). Herein, n is an integer greater than 0. Thus, signal lines of the display substrate may be reduced, and a narrow bezel design of the display substrate may be achieved. However, the present embodiment is not limited thereto.

In some examples, the first initial signal line INIT1 is configured to provide a first initial signal to the pixel circuit, and the second initial signal line INIT2 is configured to provide a second initial signal to the pixel circuit. For example, the first initial signal may be different from the second initial signal. The first initial signal and the second initial signal may be constant voltage signals, and their magnitudes may be between a first voltage signal and a second voltage signal, but are not limited thereto. In other examples, the first initial signal and the second initial signal may be the same and only the first initial signal line may be provided to provide the first initial signal.

In order to better meet people's needs for various functions and better screen experience (for example, the display screen with ultra-high screen-to-body ratio), the design of narrow bezel display screen has gradually become the mainstream form of display devices. However, in some implementations, some signal lines and circuits within the display panel are arranged in such a manner that the display panel cannot achieve a narrow bezel.

In order to realize the maximization of the display region and the extremely narrow bezel in the display screen, a curved edge design can be adopted on a large-size display panel, that is, the GOA rotates together with the Layout of pixel circuits. Due to the long wiring of the large-size display panel, Electro-Static discharge (ESD) circuits need to be connected at a rounded corner position of the curved edge (such as a upper rounded corner position) to discharge static electricity. With the narrowing of the bezel, how to place the ESD circuits reasonably without affecting the display has become an increasingly prominent problem.

An embodiment of the present disclosure provide a display substrate, which may include: a display region and a bezel region located around the display region, a plurality of sub-pixels and a plurality of data lines, and a plurality of first electrostatic discharge circuits.

The display region may include at least one corner region, the bezel region may include at least one corner region, and the at least one corner region of the display region corresponds to the at least one corner region of the bezel region.

The plurality of sub-pixels and the plurality of data lines are located in the display region, herein at least part of the plurality of sub-pixels are located in at least one corner region of the display region and arranged in a stepped shape, the plurality of data lines may include a plurality of first data lines, the plurality of first data lines D1 are electrically connected to at least part of the sub-pixels located in the at least one corner region of the display region and configured to provide data signals to the at least part of the sub-pixels.

The plurality of first electrostatic discharge circuits are located in at least one corner region of the bezel region, herein the plurality of first electrostatic discharge circuits are electrically connected to the plurality of first data lines, respectively, and configured to discharge static electricity in the plurality of first data lines.

With the display substrate provided according to this embodiment, the arrangement space occupied by the first electrostatic discharge circuits can be reduced by optimizing the setting positions of the first electrostatic discharge circuits, thereby facilitating the realization of a narrow bezel of the display substrate. In the case of realizing a narrow bezel, static electricity in the data lines in at least one corner region of the display region of the display substrate can be discharged.

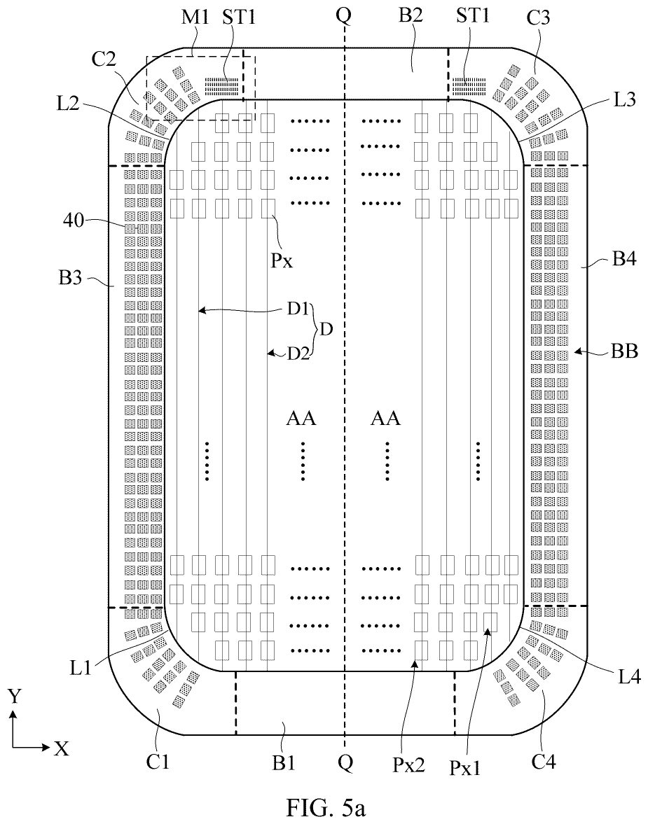

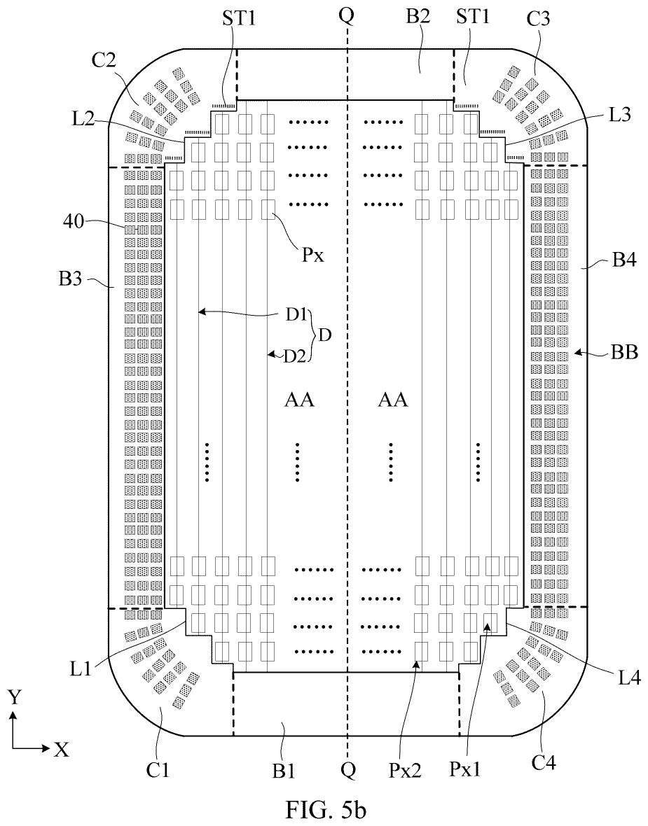

As shown in FIGS. 5a and 5b, schematic diagrams of a structure of a display device provided by an embodiment of the present disclosure, a display panel may include a display substrate, the display substrate may include: a display region AA and a bezel region BB located around the display region, a plurality of sub-pixels Px and a plurality of data lines D, and a plurality of first electrostatic discharge circuits ST1.

The display region AA may include at least one corner region, the bezel region BB may include at least one corner region, and the at least one corner region of the display region AA corresponds to the at least one corner region of the bezel region BB.

The plurality of sub-pixels Px and the plurality of data lines D are located in the display region AA; at least part of the plurality of sub-pixels Px are located in the at least one corner region of the display region AA and arranged in a stepped shape. The plurality of data lines D may include a plurality of first data lines D1, the plurality of first data lines D1 are electrically connected to at least part of the sub-pixels located in the at least one corner region of the display region AA and configured to provide data signals to the at least part of the sub-pixels Px.

The plurality of first electrostatic discharge circuits ST1 are located in at least one corner region of the bezel region BB, and the plurality of first electrostatic discharge circuits ST1 are electrically connected to the plurality of first data lines D1, respectively, and configured to discharge static electricity in the plurality of first data lines D1.

In some exemplary embodiments, as shown in FIGS. 5a and 5b, the bezel region BB may further include: a first bezel region B1 and a second bezel region B2 located on two sides of the display region AA in the second direction Y, a third bezel region B3 and a fourth bezel region B4 located on two sides of the display region AA in the first direction X. The at least one corner region of the bezel region BB may include a first corner region C1 connecting the first bezel region B1 and the third bezel region B3, a second corner region C2 connecting the third bezel region B3 and the second bezel region B2, a third corner region C3 connecting the second bezel region B2 and the fourth bezel region B4, and a fourth corner region C4 connecting the fourth bezel region B4 and the first bezel region B1.

The plurality of first electrostatic discharge circuits ST1 may be disposed in the second corner region C2 and the third corner region C3; or, the plurality of first electrostatic discharge circuits ST1 may be disposed in the first corner region C1 and the fourth corner region C4.

In the display substrate provided by an embodiment of the present disclosure, in a large-size design solution, a first electrostatic discharge circuit ST1 is disposed in at least one corner region of the bezel region BB. Under the premise of meeting the narrow bezel requirement of the large-size display substrate, the discharge of static electricity in the data lines in the corner region is satisfied. A plurality of first data lines D1 are connected to a plurality of first electrostatic discharge circuits ST1 that are placed in collection, and the wiring space can be saved under the condition of eliminating static electricity.

In an exemplary implementation, as shown in FIGS. 5a and 5b, the plurality of first electrostatic discharge circuits ST1 disposed in the first corner region C1 and the plurality of first electrostatic discharge circuits ST1 disposed in the fourth corner region C4 may be symmetrical with respect to a first midline Q-Q, which is a midline of the display substrate extending in the second direction Y.

In some other implementations, a plurality of first electrostatic discharge circuits ST1 may be disposed in each of the first corner region C1 to the fourth corner region C4, and the plurality of first electrostatic discharge circuits ST1 in the first corner region C1 and the plurality of first electrostatic discharge circuits ST1 in the fourth corner region C4 are symmetrical with respect to the first midline Q-Q.

In an implementation of the present disclosure, the plurality of first electrostatic discharge circuits ST1 located on two sides of the first midline Q-Q are arranged symmetrically with respect to the first midline Q-Q, so that the layout of the display substrate is symmetrical, and the left and right bezels (i.e., the third bezel B3 and the fourth bezel B4) are consistent.

In some exemplary implementations, as shown in FIGS. 5a and 5b, the plurality of sub-pixels Px include a plurality of sub-pixel columns, which may include a plurality of first sub-pixel columns Px1 located in the at least one corner region of the display region AA.

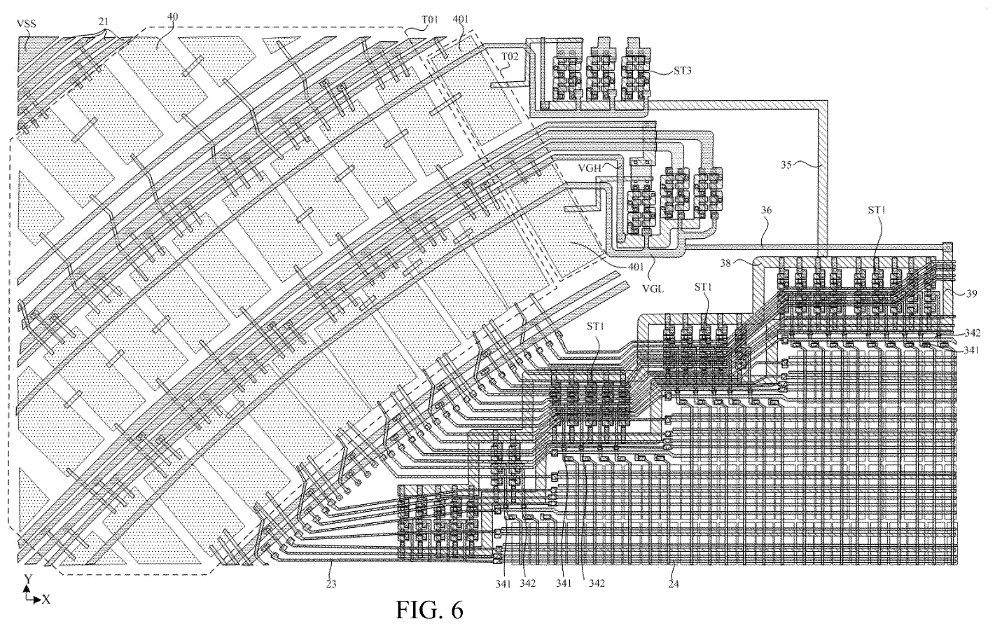

In some exemplary implementations, as shown in FIG. 6, it is a schematic partial enlarged view of the second corner region C2 in FIG. 5b. A boundary of the at least one corner region of the display region AA is in a stepped shape, a plurality of first sub-pixel columns may be arranged in a stepped shape, a plurality of first electrostatic discharge circuits ST1 may be arranged in a stepped shape, the plurality of first electrostatic discharge circuits ST1 correspond to the plurality of first sub-pixel columns Px1 in one-to-one correspondence, and the step position where any one of the first electrostatic discharge circuits ST1 is located corresponds to the step position where a corresponding first sub-pixel column Px1 is located. As shown in FIG. 6, five step positions are shown, in any one step position, a plurality of first electrostatic discharge circuits ST1 correspond to a plurality of corresponding first sub-pixel columns Px1 in one-to-one correspondence, and the first electrostatic discharge circuits ST1 and first sub-pixel columns Px1 which are corresponding to each other are arranged in the second direction Y. For example, in the upper left corner region of the display substrate shown in FIG. 6, the first electrostatic discharge circuits ST1 are located on the upper side of the corresponding first sub-pixel columns Px1.

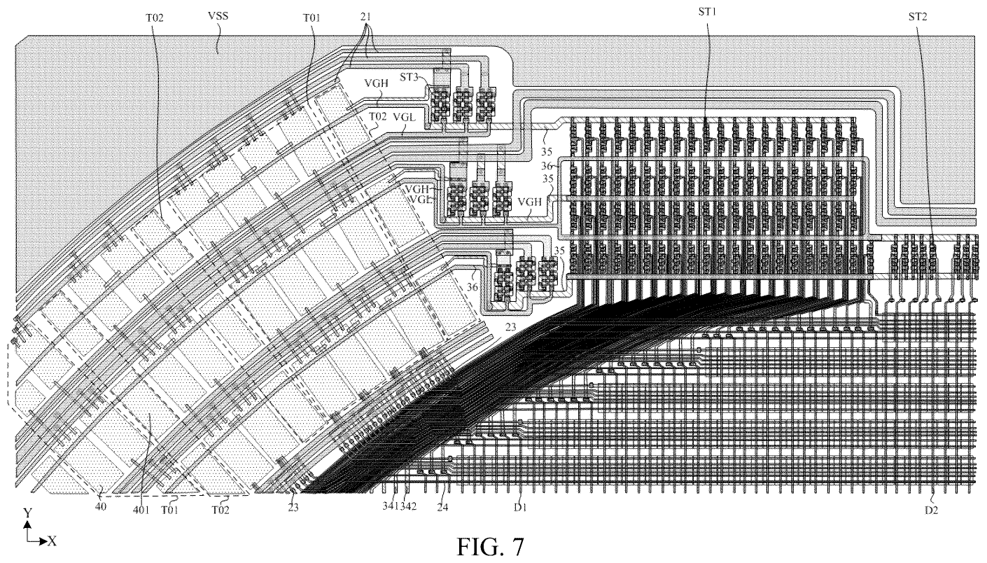

In some exemplary implementations, as shown in FIG. 7, which is an enlarged schematic diagram of the M1 region in FIG. 5a (i.e., an enlarged schematic diagram of a partial structure of the second corner region C2), the boundary of the at least one corner region of the display region AA is arc-shaped, a plurality of first electrostatic discharge circuits ST1 are arranged in an array and are located on a side of at least one corner region close to the display region AA, and the plurality of first electrostatic discharge circuits ST1 correspond to a plurality of first sub-pixel columns Px1 in a one-to-one correspondence.

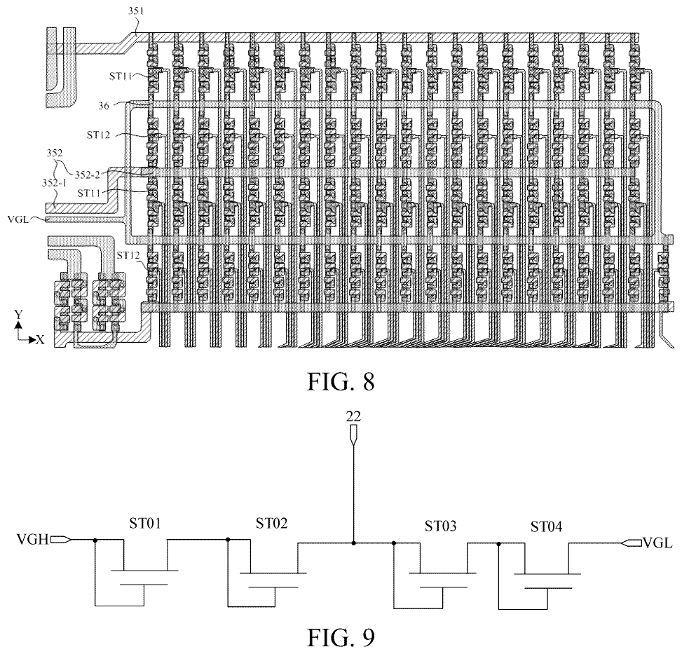

In some exemplary implementations, as shown in FIGS. 7 and 8, the plurality of first electrostatic discharge circuits ST1 located in the same column may include a plurality of first electrostatic discharge sub-circuits ST11 and a plurality of second electrostatic discharge sub-circuits ST12, the first electrostatic discharge sub-circuits ST11 and the second electrostatic discharge sub-circuits ST12 are alternately arranged in the second direction Y. As shown in FIG. 8, the plurality of first electrostatic discharge circuits ST1 arranged in an array may include 4 rows and 20 columns of first electrostatic discharge circuits ST1, and the numbers of rows and columns of the first electrostatic discharge circuits ST1 may be set according to the size of the corner of the display substrate bezel, and is not limited to that shown in FIGS. 7 and 8.

As shown in FIG. 9, there is an equivalent circuit diagram of an electrostatic discharge circuit according to at least one embodiment of the present disclosure. In some examples, as shown in FIG. 9, at least one electrostatic discharge circuit is connected to a second signal line 22 and is configured to discharge static electricity in the second signal line 22 to which it is connected. For example, a second signal line to which a first electrostatic discharge circuit is connected may be a first data line D1. One electrostatic discharge circuit may include a first discharge transistor ST01 to a fourth discharge transistor ST04. A first electrode and a gate of the first discharge transistor ST01 are electrically connected to a third power supply line VGH, a second electrode of the first discharge transistor ST01 is electrically connected to a first electrode and a control electrode of the second discharge transistor ST02, a second electrode of the second discharge transistor ST02 is electrically connected to the second signal line 22 corresponding to the electrostatic discharge circuit, a first electrode and a control electrode of the third discharge transistor ST03 are electrically connected to the second signal line 22 corresponding to the electrostatic discharge circuit, a second electrode of the third discharge transistor ST03 is electrically connected to a first electrode and a control electrode of the fourth discharge transistor ST04, and a second electrode of the fourth discharge transistor ST04 is electrically connected to a fourth power supply line VGH.

In an example, damage due to discharge breakdown caused by static electricity accumulation in the second signal line 22 may be prevented by providing the electrostatic discharge circuit, so as to discharge the static electricity accumulated in the second signal line 22 and to protect the second signal line. For example, the second signal line 22 may be connected to the first data line D1 to discharge static electricity in the first data line D1.

In another example, the electrostatic discharge circuit may include two discharge transistors, one electrode of each discharge transistor is connected to its own control electrode, thereby forming an equivalent diode connection. A signal line to be protected is connected between the two “diodes”, and other two terminals of the two “diodes” are respectively connected to the third power supply line VGH and the fourth power supply line VGL. Therefore, when an instantaneous high voltage (e.g., 100V) occurs due to accumulation of positive charges in the signal line, one of the “diodes” is turned on to discharge the positive charges in the signal line, and when an instantaneous low voltage (e.g., −100V) occurs due to accumulation of negative charges in the signal line, the other of the “diodes” is turned on to discharge the negative charges in the signal line.

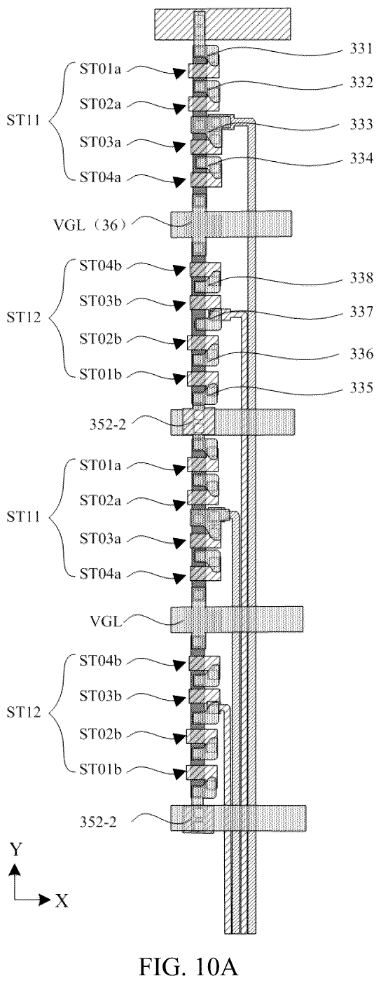

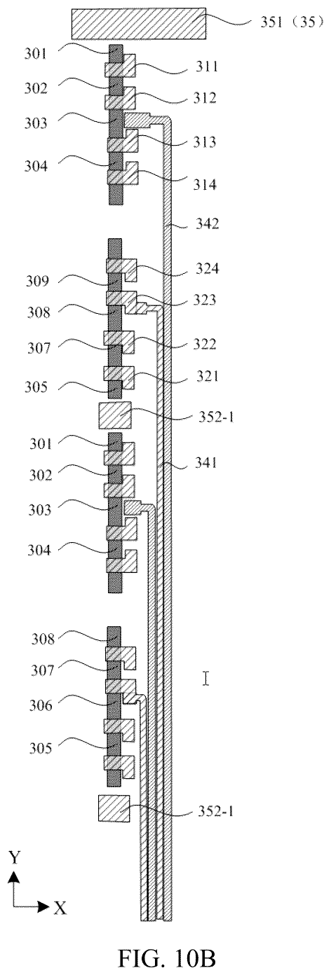

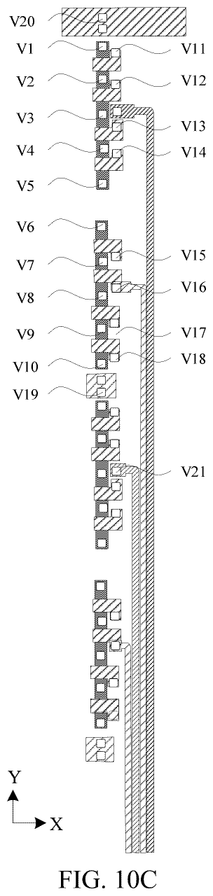

In some exemplary implementations, an arrangement direction of a plurality of discharge transistors included in the first electrostatic discharge sub-circuit ST11 and an arrangement direction of a plurality of discharge transistors included in the second electrostatic discharge sub-circuit ST12 are opposite to each other, as shown in FIG. 10A.

In some exemplary implementations, as shown in FIG. 10A, there is a schematic diagram of a structure of an electrostatic discharge circuit according to at least one embodiment of the present disclosure. FIG. 10B is a schematic diagram of the electrostatic discharge circuit after a second conductive layer is formed in FIG. 10A. FIG. 10C is a schematic diagram of the electrostatic discharge circuit after a third insulation layer is formed in FIG. 10A. FIG. 10A is a schematic diagram of an electrostatic discharge circuit after the third conductive layer is formed. Two first electrostatic discharge sub-circuits and two second electrostatic discharge sub-circuits are illustrated in FIG. 10A to FIG. 10C as an example. The equivalent circuit diagrams of the first electrostatic discharge sub-circuit ST11 and the second electrostatic discharge sub-circuit ST12 are both shown in FIG. 9. For example, the first electrostatic discharge sub-circuit ST11 may include a first discharge transistor ST01a to a fourth discharge transistor ST04a, and the second electrostatic discharge sub-circuit ST12 may include a first discharge transistor ST01b to a fourth discharge transistor ST04b.

In some examples, as shown in FIG. 10A to FIG. 10B, orthographic projections of a first active layer 301 of the first discharge transistor ST01a, a second active layer 302 of the second discharge transistor ST02a, a third active layer 303 of the third discharge transistor ST03a, and a fourth active layer 304 of the fourth discharge transistor ST04a of the first electrostatic discharge sub-circuit ST11 on the base substrate may be rectangular, and may be arranged in sequence along the second direction Y. The first active layer 301 of the first discharge transistor ST01a and the second active layer 302 of the second discharge transistor ST02a may be of an integral structure, the third active layer 303 of the third discharge transistor ST03a and the fourth active layer 304 of the fourth discharge transistor ST04a may be of an integral structure, or the first active layer 301 of the first discharge transistor ST01a, the second active layer 302 of the second discharge transistor ST02a, the third active layer 303 of the third discharge transistor ST03a, and the fourth active layer 304 of the fourth discharge transistor ST04a may be of an integral structure. Orthographic projections of a first active layer 305 of the first discharge transistor ST01b, a second active layer 306 of the second discharge transistor ST02b, a third active layer 307 of the third discharge transistor ST03b, and a fourth active layer 308 of the fourth discharge transistor ST04b of the second electrostatic discharge sub-circuit ST12 on the base substrate may be rectangular, and may be arranged in sequence along the second direction Y. The arrangement direction of the four discharge transistors of the second electrostatic discharge sub-circuit and the arrangement direction of the four discharge transistors of the first electrostatic discharge sub-circuit may be opposite to each other. The first active layer 305 of the first discharge transistor ST01b and the second active layer 306 of the second discharge transistor ST02b may be of an integral structure, the third active layer 307 of the third discharge transistor ST03b and the fourth active layer 308 of the fourth discharge transistor ST04b may be of an integral structure, or the first active layer 305 of the first discharge transistor ST01b, the second active layer 306 of the second discharge transistor ST02b, the third active layer 307 of the third discharge transistor ST03b, and the fourth active layer 308 of the fourth discharge transistor ST04b may be of an integral structure.

In some examples, as shown in FIGS. 10A and 10B, the first conductive layer of the first electrostatic discharge sub-circuit ST11 may include: control electrodes of a plurality of discharge transistors of the first electrostatic discharge sub-circuit (e.g., a control electrode 311 of the first discharge transistor ST01a, a control electrode 312 of the second discharge transistor ST02a, a control electrode 313 of the third discharge transistor ST03a, and a control electrode 314 of the fourth discharge transistor ST04a), control electrodes of a plurality of discharge transistors of the second electrostatic discharge sub-circuit ST12 (e.g., a control electrode 321 of the first discharge transistor ST01b, a control electrode 322 of the second discharge transistor ST02b, a control electrode 323 of the third discharge transistor ST03b, and a control electrode 324 of the fourth discharge transistor ST04b), a first transfer connection electrode 341, a first power supply connection structure 351 of a third power supply connection line, and a second power supply connection structure 352 of the third power supply connection line (including a first power supply connection substructure 352-1). At least part of the first transfer connection electrode 341 may extend in the second direction Y. The second electrostatic discharge sub-circuit ST12 may be electrically connected to the first data line D1 through the first transfer connection electrode 341. At least part of the first power supply connection structure 351 of the third power supply connection line may be extended in the first direction X, with one end being electrically connected to the third power supply line VGH, and the other end being electrically connected to a plurality of first electrostatic discharge sub-circuits ST11, respectively. In the third power supply connection line, at least part of the first power supply connection substructure 352-1 of the second power supply connection structure 352 may be extended in the first direction X, with one end being electrically connected to a second power supply connection substructure 352-2 located in the third conductive layer through a via, and the other end being electrically connected to the third power supply line VGH located in the third conductive layer through a via. In an exemplary implementation, the control electrode 323 of the third discharge transistor ST03b may be integrally formed with the first transfer connection electrode 341.

In some examples, as shown in FIGS. 10A and 10B, the second conductive layer of the electrostatic discharge circuit may include a second transfer connection electrode 342. At least part of the second transfer connection electrode 342 may extend in the second direction Y, and the first electrostatic discharge sub-circuit ST11 may be electrically connected to the first data line D1 through the second transfer connection electrode 342.

In some examples as shown in FIG. 10C, the third insulation layer of the bezel region BB may be provided with a plurality of vias, which may include, for example, a first via V1 to a twenty-first via V21. The third insulation layer, the second insulation layer and the first insulation layer in the first via V1 to the tenth via V10 may be removed to expose a surface of the active layer of the electrostatic discharge sub-circuit. The third insulation layer and the second insulation layer within the eleventh via V11 to the twentieth via V20 may be removed to expose a surface of the first conductive layer. The third insulation layer within the twenty-first via V21 may be removed to expose a surface of the second conductive layer.

In some examples, as shown in FIG. 10A, the third conductive layer of the electrostatic discharge sub-circuit may include a plurality of connection electrodes (e.g. a first connection electrode 331 to an eighth connection electrode 338). The first connection electrode 331 may be electrically connected to the first active layer 301 of the first discharge transistor ST01a of the first electrostatic discharge sub-circuit through the first via V1, may be electrically connected to the first power supply connection structure 351 through the twentieth via V20, and may be electrically connected to the control electrode 311 of the first discharge transistor ST01a through the eleventh via V11. The second connection electrode 332 may be electrically connected to the second active layer 302 of the second discharge transistor ST02a through the second via V2, and may also be electrically connected to the control electrode 312 of the second discharge transistor ST02a through the twelfth via V12. The third connection electrode 333 may be electrically connected to the control electrode 312 of the third discharge transistor ST03a through the thirteenth via V13, may be electrically connected to the second active layer 302 of the third discharge transistor ST03a and the third active layer 303 of the third discharge transistor ST03a through the third via V3, and may be electrically connected to the second transfer connection electrode 342 through the twenty-first via V21. The fourth connection electrode 334 may be electrically connected to the control electrode 314 of the fourth discharge transistor ST04a through the fourth via V4, and may also be electrically connected to the third active layer 304 of the fourth discharge transistor ST04a through the fourteenth via V14. The second power supply line VGL may be reused as a second electrode of the fourth discharge transistor ST04a, and electrically connected to the active layer 304 of the fourth discharge transistor ST04a through the fifth via V5. The fifth connection electrode 335 may be electrically connected to the first active layer 305 of the first discharge transistor ST01b through the tenth via V10, may be electrically connected to the control electrode 321 of the first discharge transistor ST01b through the eighteenth via V18, and may be electrically connected to the first power supply connection substructure 352-1 through the tenth via V10 and the nineteenth via V19. The sixth connection electrode 336 may be electrically connected to the fourth active layer 306 of the second discharge transistor ST02b of the second electrostatic discharge circuit through the ninth via V9, and may also be electrically connected to the control electrode 322 of the second discharge transistor ST02b through the seventeenth via V17. The seventh connection electrode 337 may be electrically connected to the third active layer 307 of the third discharge transistor ST03b through the eighth via V8, and may also be electrically connected to the control electrode 323 of the third discharge transistor ST02b through the sixteenth via V16. The eighth connection electrode 338 may be electrically connected to the fourth active layer 308 of the fourth discharge transistor ST04b through the seventh via V7, and may also be electrically connected to the control electrode 324 of the fourth discharge transistor ST04b through the fifteenth via V15. In the structure shown in FIGS. 10A to 10B, a second electrode of the first discharge transistor ST01a shares a connection electrode 332 with a first electrode of the second discharge transistor ST02a, a second electrode of the second discharge transistor ST02a shares a connection electrode 333 with a first electrode of the third discharge transistor ST03a, and a second electrode of the third discharge transistor ST03a shares a connection electrode 334 with a first electrode of the fourth discharge transistor ST04a. A second electrode of the first discharge transistor ST01b shares a connection electrode 336 with a first electrode of the second discharge transistor ST02b, a second electrode of the second discharge transistor ST02b shares a connection electrode 337 with a first electrode of the third discharge transistor ST03b, and a second electrode of the third discharge transistor ST03b shares a connection electrode 338 with a first electrode of the fourth discharge transistor ST04b.

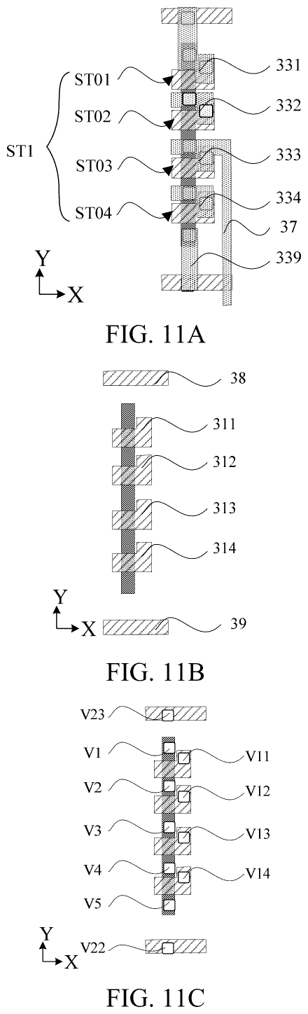

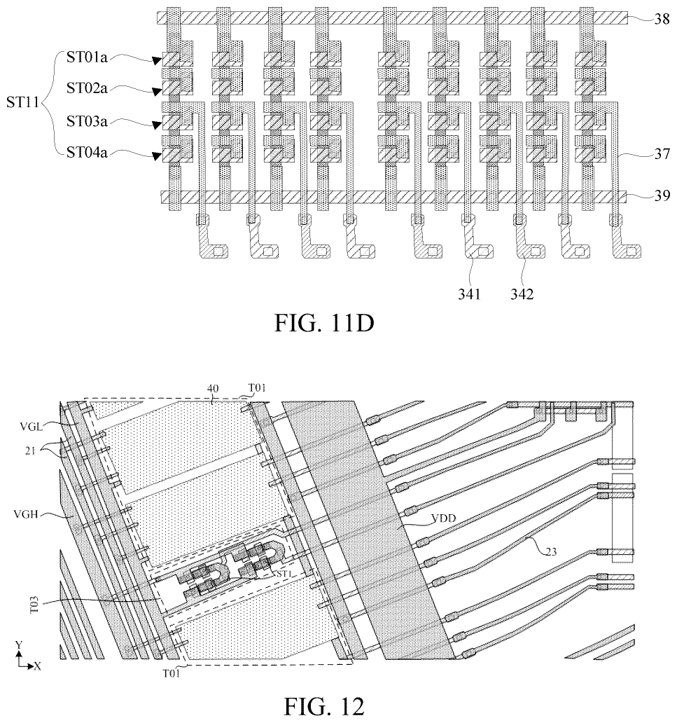

FIG. 11A is another diagram of a structure of an electrostatic discharge circuit according to at least one embodiment of the present disclosure. FIG. 11B is a schematic diagram of the electrostatic discharge circuit after a second conductive layer is formed in FIG. 11A, and FIG. 11C is a schematic diagram of the electrostatic discharge circuit after a third insulation layer is formed in FIG. 11A. FIG. 11A is a schematic diagram of the electrostatic discharge circuit after a third conductive layer is formed. In this example, as shown in FIG. 6, a plurality of first electrostatic discharge circuits ST1 are arranged in a stepped shape, and the plurality of first electrostatic discharge circuits ST1 at the same step position are arranged in the first direction X. The third conductive layer may also be provided with a third transfer connection electrode 37. The third transfer connection electrode 37 and a first electrode 333 of the third discharge transistor ST03 may be of an integrally formed structure. As shown in FIG. 11D, there is a schematic diagram of a structure of a plurality of first electrostatic discharge circuits ST11 corresponding to one step position in FIG. 6. A plurality of first transfer connection electrodes 341 and a plurality of second transfer connection electrodes 342 may be electrically connected to the plurality of first discharge transistors ST1 through third transfer connection electrodes 37. One end of the first electrostatic discharge circuit ST1 is electrically connected to a third power supply connection electrode 38, and the other end is electrically connected to a fourth power supply connection electrode 39. The fourth power supply connection electrode 39 is electrically connected to a second electrode 339 of the fourth discharge transistor ST04 through the twenty-second via V22, and the third power supply connection electrode 38 is electrically connected to a first electrode 331 of the first discharge transistor ST01 through the twenty-third via V23. In the structures shown in FIG. 11A to FIG. 11B, a second electrode of the first discharge transistor ST01 shares a connection electrode 332 with a first electrode of the second discharge transistor ST02, a second electrode of the second discharge transistor ST02 shares a connection electrode 333 with a first electrode of the third discharge transistor ST03, and a second electrode of the third discharge transistor ST03 shares a connection electrode 334 with a first electrode of the fourth discharge transistor ST04. The rest of the structure of the electrostatic discharge circuit according to the present embodiment may refer to descriptions of the aforementioned embodiments, and thus will not be repeated here.

In some exemplary implementations, as shown in FIGS. 5a, 5b and 7, the plurality of sub-pixel columns may further include a plurality of second sub-pixel columns Px2, the plurality of data lines may further include a plurality of second data lines D2 that provide data signals to sub-pixels in the plurality of second sub-pixel columns Px2 respectively, and the first bezel region B1 or the second bezel region B2 may further be provided with a plurality of second electrostatic discharge circuits ST2. The plurality of second electrostatic discharge circuits ST2 are electrically connected to the plurality of second data lines D2 respectively and are configured to discharge static electricity in the plurality of second data lines D2. The plurality of second electrostatic discharge circuits ST2 correspond to the plurality of second sub-pixel columns Px2, e.g., in one-to-one correspondence.

In some exemplary implementations, as shown in FIG. 5a to FIG. 7, the display substrate may also include a plurality of drive signal lines 21 and a plurality of third electrostatic discharge circuits ST3 located in the bezel region BB. The plurality of third electrostatic discharge circuits ST3 are electrically connected to the plurality of drive signal lines 21, respectively, and are configured to discharge static electricity in the drive signal lines 21. The plurality of drive signal lines are located in the third bezel region B3 and the fourth bezel region B4. The drive signal lines 21 located in the third bezel region B3 extend to the first corner region C1 and the second corner region C2, and the drive signal lines located in the fourth bezel region B4 extend to the third corner region C3 and the fourth corner region C4. The third electrostatic discharge circuits ST3 are provided in the first corner region C1 and the fourth corner region C4, or the third electrostatic discharge circuits ST3 are provided in the second corner region C2 and the third corner region C3.

In an embodiment of the present disclosure, in a large-size design solution, a third electrostatic discharge circuit ST3 is provided in at least one corner region of the bezel, and a plurality of drive signal lines 21 located in the bezel region are connected to a plurality of third electrostatic discharge circuits ST3 that are placed in collection, thereby saving wiring space while eliminating static electricity, and facilitating the realization of a narrow bezel of the display substrate. In an exemplary implementation, as shown in FIGS. 6 and 7, there may be various drive signal lines 21, for example, the drive signal lines 21 may include clock signal lines, gate drive signal lines, initial signal power supply lines, and the like.

In some exemplary implementations, as shown in FIGS. 6 and 7, the display substrate may also include a third power supply line VGH and a fourth power supply line VGL located in the bezel region BB. The plurality of third electrostatic discharge circuits ST3 and the plurality of first electrostatic discharge circuits ST1 are electrically connected to the third power supply line VGH and the fourth power supply line VGL. The third power supply line VGH and the fourth power supply line VGL are located in the third bezel region B3 and the fourth bezel region B4. The third power supply line VGH and the fourth power supply line VGL located in the third bezel region B3 extend to the first corner region C1 and the second corner region C2, and the third power supply line VGH and the fourth power supply line VGL located in the fourth bezel region B4 extend to the third corner region C3 and the fourth corner region C4.

In some exemplary implementations, as shown in FIGS. 5a to 7, the display substrate may also include a plurality of drive circuits 40 located in the bezel region BB, the drive circuits 40 are located in the third bezel region B3, the fourth bezel region B4, the first corner region C1, the second corner region C2, the third corner region C3, and the fourth corner region C4.

The plurality of drive circuits 40 are electrically connected to the plurality of drive signal lines 21, the third power supply line VGH, and the fourth power supply line VGL.

In an exemplary implementation, the plurality of drive circuits 40 may include gate drive circuits.

In some exemplary implementations, as shown in FIG. 12, the display substrate may further include a plurality of effective drive circuit regions T01 (regions corresponding to the drive circuits 40), a plurality of first virtual drive circuit regions T02 (regions corresponding to a plurality of virtual drive circuits 401 are not shown in FIG. 12, FIGS. 6 and 7 show the virtual drive circuits 401) and a plurality of second virtual drive circuit regions T03 (regions corresponding to a plurality of first electrostatic discharge circuits ST1) located in the bezel region BB. The plurality of effective drive circuit regions are arranged in the extending direction of the bezel region BB, and the plurality of first virtual drive circuit regions T02 and the plurality of second virtual drive circuit regions T03 are disposed alternately between the plurality of effective drive circuit regions T01. The plurality of effective drive circuit regions T01 are provided with a plurality of drive circuits 40 respectively, and the plurality of first virtual drive circuit regions T02 are provided with a plurality of virtual drive circuits 401 respectively. The plurality of second virtual drive circuit regions T03 are located in a corner region of the bezel region, and the plurality of first electrostatic discharge circuits ST1 are provided in the plurality of second virtual drive circuit regions T02. The configuration of the virtual drive circuits 401 may be shown with reference to FIGS. 6 and 7. The virtual drive circuits 401 are not electrically connected to the display region AA and the drive signal line 21. During the actual preparation of the display substrate, the virtual drive circuits 401 (Dummy GOA) are formed in a blank region of the bezel region, which can improve the uniformity of the process. In an embodiment of the present disclosure, the first electrostatic discharge circuit ST1 is prepared by using the blank region of an area where the virtual drive circuit 401 is prepared, so that the blank region can be used reasonably, and static electricity in the data line D can be discharged without increasing the bezel.

In some exemplary implementations, as shown in FIG. 12, the display substrate may further include a third power supply line VGH, a fourth power supply line VGL, a plurality of drive signal lines 21, and a plurality of third electrostatic discharge circuits ST3 located in the bezel region BB. The plurality of third electrostatic discharge circuits ST3 are electrically connected to the plurality of drive signal lines, respectively, and are configured to discharge static electricity in the plurality of drive signal lines; the plurality of third electrostatic discharge circuits ST3 and the plurality of first electrostatic discharge circuits ST1 are electrically connected to the third power supply line VGH and the fourth power supply line VGL. The third electrostatic discharge circuit ST3 is not shown in FIG. 12 and may be shown with reference to FIGS. 6 and 7.

In some exemplary implementations, in a direction perpendicular to a plane where the display region AA substrate is located, the display region AA substrate may include a base substrate, as well as a semiconductor layer, a first conductive layer, a second conductive layer, a third conductive layer and a fourth conductive layer stacked sequentially on the base substrate. The first conductive layer may include a plurality of first transfer connection electrodes 341, and the second conductive layer may include a plurality of second transfer connection electrodes 342. The plurality of first transfer connection electrodes 341 and the plurality of second transfer connection electrodes 342 are alternately arranged in the first direction X, with one ends being electrically connected to a plurality of first data lines D respectively, and the other ends being electrically connected to a plurality of first electrostatic discharge circuits ST1 respectively.

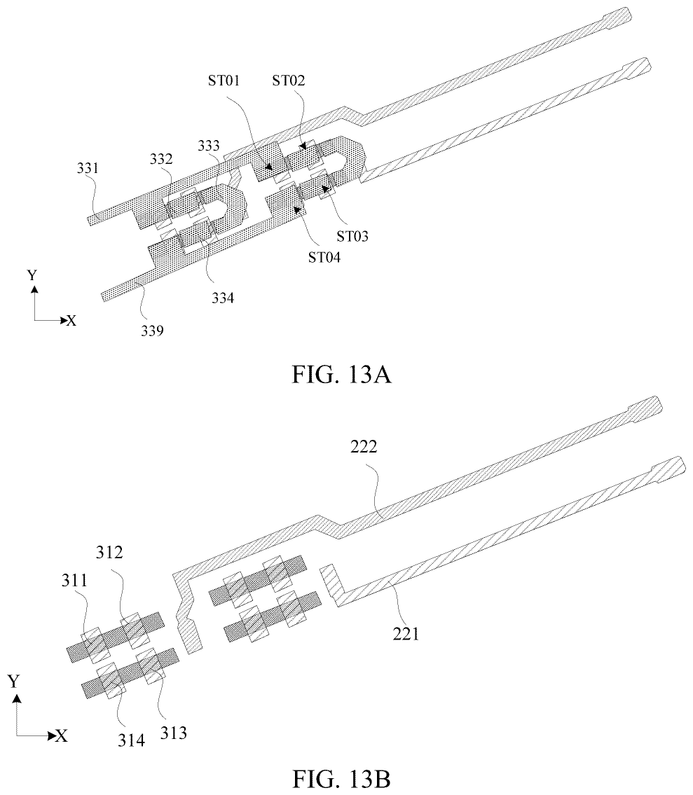

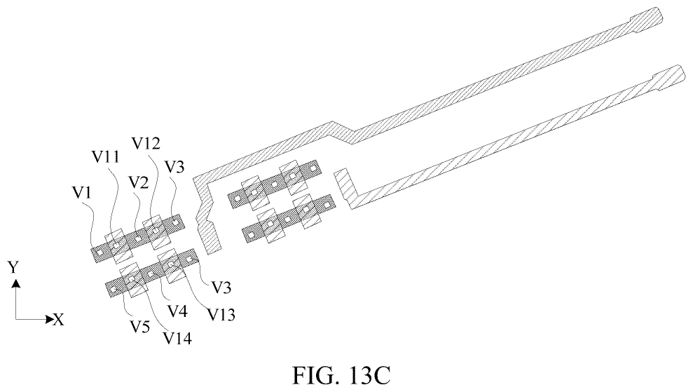

The circuit structure of the first electrostatic discharge circuit ST1 in FIG. 12 may be shown in FIGS. 13A to 13C, and FIG. 13A is another schematic diagram of a structure of an electrostatic discharge circuit according to at least one embodiment of the present disclosure. FIG. 13B is a schematic diagram of the electrostatic discharge circuit after a second conductive layer is formed in FIG. 13A, and FIG. 13C is a schematic diagram of the electrostatic discharge circuit after a third insulation layer is formed in FIG. 13A. In this example, as shown in FIG. 12, a plurality of first electrostatic discharge circuits ST1 are provided in a second virtual drive circuit region T03 between two adjacent drive circuits 40. A plurality of first electrostatic discharge circuits ST1 may be provided in the same second virtual drive circuit region T03, for example, two first electrostatic discharge circuits ST1 may be provided. The two first electrostatic discharge circuits ST1 may be electrically connected to two first data lines D1, respectively. The two first electrostatic discharge circuits ST1 may be arranged along a radial extension direction where the arc circumference of a corner region of the bezel region BB is located. First electrostatic discharge transistors ST01 in the two first electrostatic discharge circuits ST1 share a first electrode 331, which is electrically connected to the third power supply line VGH, and fourth electrostatic discharge transistors ST04 in the two first electrostatic discharge circuits ST1 share a second electrode 339, which may be integrally formed with the fourth power supply line VGL. A second electrode of a second electrostatic discharge transistor ST02 and a third electrode of a third electrostatic discharge transistor ST03 in the first electrostatic discharge circuit ST1 may share a connection electrode 333. The connection electrode 333 may be electrically connected to a first data line D1 in the display region through a first interlayer transfer connection electrode 221 or a second interlayer transfer connection electrode 222. The first interlayer transfer connection electrode 221 may be provided in the first conductive layer, and the second interlayer transfer connection electrode 222 may be provided in the second conductive layer. The rest of the structure of the electrostatic discharge circuit according to the present embodiment may refer to descriptions of the aforementioned embodiments, and thus will not be repeated here.

In some exemplary implementations, as shown in FIGS. 5a to 7, the display substrate may further include: a plurality of first connection lines 23; a plurality of first signal lines 24 located in the display region AA; and a plurality of drive circuits 40, a plurality of third electrostatic discharge circuits ST3, and a plurality of drive signal lines located in the bezel region BB.

In a direction parallel to a plane where the display region AA substrate is located, the plurality of first signal lines 24 extend in the first direction X and are arranged in the second direction, a plurality of data lines D are arranged in the first direction X and extending in the second direction Y; and the plurality of first signal lines 24 and the plurality of data lines D are provided in different layers.

One ends of the plurality of first connection lines 23 are electrically connected to the plurality of first signal lines 24 respectively, and the other ends of the plurality of first connection lines 23 are electrically connected to the plurality of drive circuits 40 and the plurality of drive signal lines 21, respectively.

In some exemplary implementations, as shown in FIGS. 7 and 8, a plurality of first electrostatic discharge circuits ST1 are arranged in an array, at least part of the first transfer connection electrodes 341 and the second transfer connection electrodes 342 are in an arc-shaped structure, the first electrostatic discharge circuit ST1 is electrically connected to one of the first data lines D through the arc-shaped first transfer connection electrode 341 or second transfer connection electrode 342, and a plurality of drive signal lines 21 are provided in the third conductive layer.

The first connection line 23 and at least part of the first signal lines 24 may be provided in the third conductive layer, and a plurality of data lines D may be provided in the fourth conductive layer. Or, the first connection line 23 and at least part of the first signal lines 24 may be provided in the fourth conductive layer, and a plurality of data lines D may be provided in the third conductive layer.

In an exemplary implementation, the first signal line 24 may include: a gate line, a scan signal line, an initial signal line, and the like.

In some exemplary implementations, as shown in FIG. 7, the display substrate may further include: a plurality of third power supply lines VGH and a plurality of fourth power supply lines VGL located in the bezel region BB; and a plurality of third power supply connection lines 35 and a plurality of fourth power supply connection lines 36 located in at least one corner region of the bezel region BB. One ends of the plurality of third power supply connection lines 35 are electrically connected to the plurality of third power supply lines VGH respectively, and the other ends thereof are electrically connected to the plurality of third electrostatic discharge circuits ST3 and the plurality of first electrostatic discharge circuits ST1, respectively. One ends of the plurality of fourth power supply connection lines 36 are electrically connected to the plurality of fourth power supply lines VGL respectively, and the other ends thereof are electrically connected to the plurality of third electrostatic discharge circuits ST3 and the plurality of first electrostatic discharge circuits ST1, respectively.

The plurality of third electrostatic discharge circuits ST3, the plurality of third power supply connection lines 35, and the plurality of fourth power supply connection lines 36 may be arranged in a stepped shape, and the third power supply connection lines 35 and the fourth power supply connection lines 36 may be in a shape of a bending line extending in the first direction X.

In some exemplary embodiments, as shown in FIGS. 7 and 8, the plurality of third power supply lines VGH, the plurality of fourth power supply lines VGL, and the plurality of fourth power supply connection lines 36 are provided in the third conductive layer. The plurality of third power supply connection lines 35 include one first power supply connection structure 351 and a plurality of second power supply connection structures 352. The one first power supply connection structure 351 is provided in the first conductive layer, and is electrically connected to one third power supply line of the third power supply lines VGH, at least part of the third electrostatic discharge circuit ST3, and a plurality of first electrostatic discharge circuits ST1 in a first row. The second power supply connection structure 352 may include a first power supply connection substructure 352-1 and a second power supply connection substructure 352-2. The first power supply connection substructure 352-1 may be in a shape of a bending line and provided in the first conductive layer, and electrically connected to a plurality of third electrostatic discharge sub-circuits ST3, a plurality of third power supply lines VGH, and the second power supply connection substructure 352-2. The second power supply connection substructure 352-2 may be provided in the third conductive layer and electrically connected to the first power supply connection substructure 352-1 and a plurality of first electrostatic discharge circuits ST1.

In some exemplary implementations, as shown in FIGS. 6 and 11A, a partially enlarged structure of the first electrostatic discharge circuit ST1 in FIG. 6 may be shown in FIG. 11A. A plurality of first electrostatic discharge circuits ST1 may be arranged in a stepped shape. The bezel region BB may further include a plurality of third transfer connection electrodes 37, the plurality of third transfer connection electrodes 37 are arranged in a stepped shape. A plurality of first transfer connection electrodes 341 and a plurality of second transfer connection electrodes 342 are electrically connected to the plurality of first electrostatic discharge circuits ST1 through a plurality of third transfer connection electrodes 37, respectively.

A plurality of third transfer connection electrodes 37 may be provided in the third conductive layer, a plurality of data lines D may be provided in the fourth conductive layer, and a plurality of first signal lines 24 may be provided in one or more layers of the first conductive layer to the third conductive layer.

In some exemplary implementations, as shown in FIG. 6, the display substrate may also include a third power supply line VGH and a fourth power supply line VGL located in the bezel region BB; a plurality of third power supply connection lines 35, a plurality of fourth power supply connection lines 36, a third power supply connection electrode 38 and a fourth power supply connection electrode 39 located in at least one corner region of the bezel region BB.

One ends of the plurality of third power supply connection lines 35 are electrically connected to the plurality of third power supply lines VGH respectively, and the other ends thereof are electrically connected to the plurality of third electrostatic discharge circuits ST3, respectively; one of the third power supply connection lines 35 is electrically connected to the third power supply connection electrode 38, and one of the fourth power supply connection lines 36 is electrically connected to the fourth power supply connection electrode 39.

The third power supply connection electrode 38 is electrically connected to one of the third power supply connection lines 35 and one ends of the plurality of first electrostatic discharge circuits ST1, and the fourth power supply connection electrode 39 is electrically connected to one of the fourth power supply connection lines 36 and the other ends of the plurality of first electrostatic discharge circuits ST1.

In some exemplary implementations, as shown in FIG. 6, the plurality of third electrostatic discharge circuits ST3, the plurality of third power supply connection lines 35, and the plurality of fourth power supply connection lines 36 may be arranged in a stepped shape, the third power supply connection lines 35 and the fourth power supply connection lines 36 may be of a blending line structure extending in the first direction X, and the third power supply connection electrode 38 and the fourth power supply connection electrode 39 may be in a stepped blending line structure, and the extending directions thereof are consistent with the extending direction of the corresponding corner region in the bezel region BB.

The third power supply line VGH, the fourth power supply line VGL, and the fourth power supply connection line 36 may be provided in the third conductive layer, while the third power supply connection line 35, the third power supply connection electrode 38, and the fourth power supply connection electrode 39 may be provided in the first conductive layer.

In an embodiment of the present disclosure, a VSS shown in FIGS. 6 and 7 may be a second power supply line configured to provide a power supply signal to a light emitting element, and a VDD in FIG. 12 may be a first power supply line configured to provide a power supply signal to the sub-pixels of the display region. With the solution provided by the embodiment of the present disclosure, electrostatic discharge can be realized on the premise of realizing a narrow bezel. On the premise of not narrowing the first power supply line VDD and the second power supply line VSS, by placing at different positions, lines in a corner region of the bezel can be connected to an electrostatic discharge circuit to complete the operation of electrostatic elimination, thereby preventing electrostatic breakdown and improving product yield.

An embodiment of the present disclosure further provides a display device including the display substrate according to any one of the aforementioned embodiments, and light emitting elements disposed in the display region of the display substrate, herein the light emitting elements are arranged in an array.

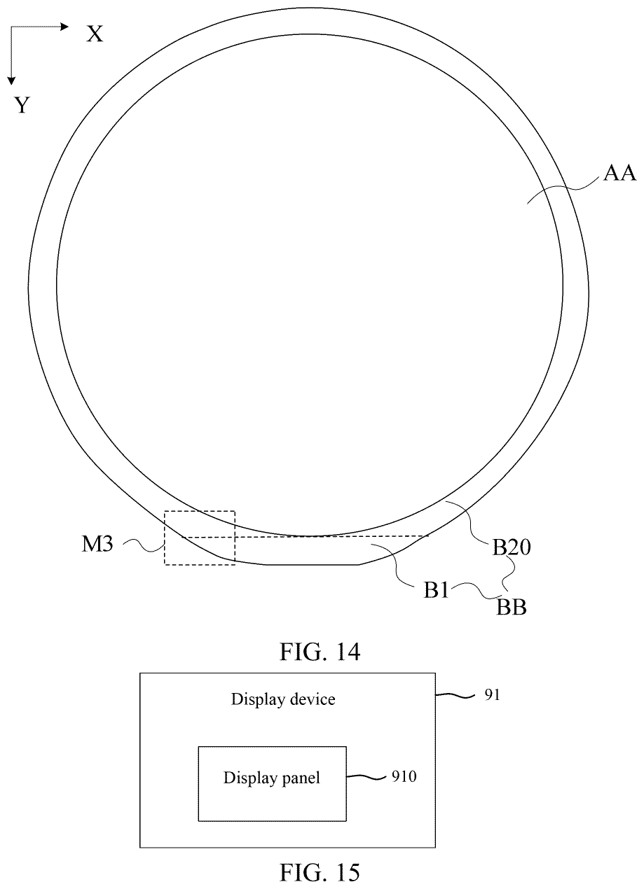

FIG. 14 is another schematic diagram of a display device according to at least one embodiment of the present disclosure. In some examples, as shown in FIG. 14, the display device may include a display substrate. The display substrate may include a display region AA and a bezel region BB located around the display region AA. The bezel region may include a first bezel region B1 located on a side of the display region AA and a rest bezel region B20 located on rest sides. In this example, the display substrate may be circular or oval. An enlarged schematic view of the M3 region in FIG. 14 may be shown in FIG. 12. The rest of the structure of the display substrate according to the embodiment of the present disclosure may refer to descriptions of the aforementioned embodiments, and will not be repeated here.

In an implementation of the present disclosure, the equivalent circuit diagrams of the first electrostatic discharge circuit ST1, the second electrostatic discharge circuit ST2, and the third electrostatic discharge circuit ST3 may be as shown in FIG. 9, but are not limited to the equivalent circuit shown in FIG. 9.

The structure of the display substrate of the exemplary embodiment of the present disclosure is described only as an example. In some exemplary implementations, a corresponding structure may be changed and a patterning process may be added or reduced according to actual needs. For example, the display region may be provided with a first semiconductor layer and a third conductive layer, the third conductive layer may include source electrodes and drain electrodes of transistors, and a fourth conductive layer may include connection electrodes between light emitting elements and the drain electrodes of the transistors. However, the present embodiment is not limited thereto.

FIG. 15 is a schematic diagram of a display device according to at least one embodiment of the present disclosure. In some examples, the display panel 910 may be an OLED display panel. A display device 91 may be any product or component with a display function, such as an OLED display device, a mobile phone, a tablet computer, a television, a display, a notebook computer, a digital photo frame, or a navigator. However, the present embodiment is not limited thereto.

With the display substrate and the display device provided according to embodiments of the present disclosure, the arrangement space occupied by first electrostatic discharge circuits can be reduced by optimizing the setting positions of the first electrostatic discharge circuits in the display substrate, thereby facilitating the realization of a narrow bezel of the display substrate. In the case of realizing a narrow bezel, static electricity in data lines in at least one corner region of the display region of the display substrate can be discharged.

The drawings in the present disclosure only refer to the structures involved in the embodiments of the present disclosure, and common designs may be referred to for other structures. The embodiments of the present disclosure, i.e., features in the embodiments, may be combined with each other to obtain new embodiments if there is no conflict. Those of ordinary skills in the art should understand that modifications or equivalent replacements may be made to the technical solutions of the embodiments of the present disclosure without departing from the spirit and scope of the technical solutions of the embodiments of the present disclosure, and should all fall within the scope of the claims of the present disclosure.

1. A display substrate, comprising:
a display region and a bezel region located around the display region, the display region comprising at least one corner region, the bezel region comprising at least one corner region, and the at least one corner region of the display region corresponding to the at least one corner region of the bezel region;
a plurality of sub-pixels and a plurality of data lines located in the display region, at least part of the plurality of sub-pixels being located in the at least one corner region of the display region and arranged in a stepped shape, the plurality of data lines comprising a plurality of first data lines, the plurality of first data lines being electrically connected to at least part of the sub-pixels located in the at least one corner region of the display region and configured to provide data signals to the at least part of the sub-pixels; and
a plurality of first electrostatic discharge circuits located in the at least one corner region of the bezel region, the plurality of first electrostatic discharge circuits being electrically connected to the plurality of first data lines, respectively, and configured to discharge static electricity in the plurality of first data lines.

2. The display substrate of claim 1, wherein the bezel region further comprises a first bezel region and a second bezel region located on two sides of the display region in a second direction, and a third bezel region and a fourth bezel region located on two sides of the display region in a first direction; the at least one corner region of the bezel region comprises a first corner region connecting the first bezel region and the third bezel region, a second corner region connecting the third bezel region and the second bezel region, a third corner region connecting the second bezel region and the fourth bezel region, and a fourth corner region connecting the fourth bezel region and the first bezel region;
the plurality of first electrostatic discharge circuits are provided in the second corner region and the third corner region; or, the plurality of first electrostatic discharge circuits are provided in the first corner region and the fourth corner region.

3. The display substrate of claim 2, wherein the plurality of sub-pixels comprise a plurality of sub-pixel columns, the plurality of sub-pixel columns comprise a plurality of first sub-pixel columns located in the at least one corner region of the display region.

4. The display substrate of claim 3, wherein a boundary of the at least one corner region of the display region has a stepped shape, the plurality of first sub-pixel columns are arranged in a stepped shape, the plurality of first electrostatic discharge circuits are arranged in a stepped shape, the plurality of first electrostatic discharge circuits correspond to the plurality of first sub-pixel columns in a one-to-one correspondence, and a step position where any one of the first electrostatic discharge circuits is located is consistent with a step position where a corresponding first sub-pixel column is located.

5. The display substrate of claim 3, wherein a boundary of the at least one corner region of the display region is arc-shaped, the plurality of first electrostatic discharge circuits are arranged in an array and located on a side of the at least one corner region close to the display region, and the plurality of first electrostatic discharge circuits correspond to the plurality of first sub-pixel columns in a one-to-one correspondence.

6. The display substrate of claim 5, wherein a plurality of first electrostatic discharge circuits located in a same column comprises a plurality of first electrostatic discharge sub-circuits and a plurality of second electrostatic discharge sub-circuits, the first electrostatic discharge sub-circuits and the second electrostatic discharge sub-circuits are alternately arranged in the second direction.

7. The display substrate of claim 6, wherein an arrangement direction of a plurality of discharge transistors comprised in the first electrostatic discharge sub-circuits and an arrangement direction of a plurality of discharge transistors comprised in the second electrostatic discharge sub-circuits are opposite to each other.

8. The display substrate of claim 3, wherein the plurality of sub-pixel columns further comprises a plurality of second sub-pixel columns, the plurality of data lines further comprise a plurality of second data lines providing data signals to sub-pixels in the plurality of second sub-pixel columns respectively, the first bezel region or the second bezel region is further provided with a plurality of second electrostatic discharge circuits, wherein the plurality of second electrostatic discharge circuits are electrically connected to the plurality of second data lines respectively and are configured to discharge static electricity in the plurality of second data lines, and the plurality of second electrostatic discharge circuits correspond to the plurality of second sub-pixel columns in a one-to-one correspondence.

9. The display substrate of claim 2, further comprising a plurality of drive signal lines and a plurality of third electrostatic discharge circuits located in the bezel region; wherein the plurality of third electrostatic discharge circuits are electrically connected to the plurality of drive signal lines respectively and are configured to discharge static electricity in the drive signal lines, the plurality of drive signal lines are located in the third bezel region and the fourth bezel region, drive signal lines located in the third bezel region extend to the first corner region and the second corner region, and drive signal lines located in the fourth bezel region extend to the third corner region and the fourth corner region; the third electrostatic discharge circuits are provided in the first corner region and the fourth corner region, or the third electrostatic discharge circuits are provided in the second corner region and the third corner region.

10. The display substrate of claim 9, further comprising a third power supply line and a fourth power supply line located in the bezel region; wherein the plurality of third electrostatic discharge circuits and the plurality of first electrostatic discharge circuits are all electrically connected to the third power supply line and the fourth power supply line; wherein the third power supply line and the fourth power supply line are located in the third bezel region and the fourth bezel region, a third power supply line and a fourth power supply line located in the third bezel region extend to the first corner region and the second corner region, and a third power supply line and a fourth power supply line located in the fourth bezel region extend to the third corner region and the fourth corner region.

11. The display substrate of claim 10, further comprising a plurality of drive circuits located in the bezel region, wherein the drive circuits are located in the third bezel region, the fourth bezel region, the first corner region, the second corner region, the third corner region, and the fourth corner region;
the plurality of drive circuits are electrically connected to the plurality of drive signal lines, the third power supply line, and the fourth power supply line.

12. The display substrate of claim 1, further comprising a plurality of effective drive circuit regions, a plurality of first virtual drive circuit regions and a plurality of second virtual drive circuit regions located in the bezel region, wherein the plurality of effective drive circuit regions are arranged along an extending direction of the bezel region, the plurality of first virtual drive circuit regions and the plurality of second virtual drive circuit regions are disposed alternately between the plurality of effective drive circuit regions, the plurality of effective drive circuit regions are respectively provided with a plurality of drive circuits, the plurality of first virtual drive circuit regions are respectively provided with a plurality of virtual drive circuits, the plurality of second virtual drive circuit regions are located in the corner region, and the plurality of first electrostatic discharge circuits are provided in the plurality of second virtual drive circuit regions.

13. The display substrate of claim 12, further comprising a third power supply line, a fourth power supply line, a plurality of drive signal lines, and a plurality of third electrostatic discharge circuits located in the bezel region; wherein the plurality of third electrostatic discharge circuits are electrically connected to the plurality of drive signal lines respectively, and are configured to discharge static electricity in the plurality of drive signal lines; wherein the plurality of third electrostatic discharge circuits and the plurality of first electrostatic discharge circuits are all electrically connected to the third power supply line and the fourth power supply line.

14. The display substrate of claim 1, wherein in a direction perpendicular to a plane where the display substrate is located, the display substrate comprises a base substrate and a semiconductor layer, a first conductive layer, a second conductive layer, a third conductive layer and a fourth conductive layer stacked sequentially on the base substrate, wherein the first conductive layer comprises a plurality of first transfer connection electrodes, the second conductive layer comprises a plurality of second transfer connection electrodes, the plurality of first transfer connection electrodes and the plurality of second transfer connection electrodes are alternately arranged in a first direction, with one ends being electrically connected to the plurality of first data lines respectively, and the other ends being electrically connected to the plurality of first electrostatic discharge circuits respectively.

15. The display substrate of claim 14, wherein the display substrate further comprises:
a plurality of first connection lines;
a plurality of first signal lines located in the display region; wherein in a direction parallel to the plane where the display substrate is located, the plurality of first signal lines extend in the first direction and are arranged in a second direction, the plurality of data lines are arranged in the first direction and extend in the second direction; and wherein the plurality of first signal lines and the plurality of data lines are arranged in different layers; and
a plurality of drive circuits, a plurality of third electrostatic discharge circuits and a plurality of drive signal lines located in the bezel region; wherein one ends of the plurality of first connection lines are electrically connected to the plurality of first signal lines respectively, and the other ends of the plurality of first connection lines are electrically connected to the plurality of drive circuits and the plurality of drive signal lines respectively.

16. The display substrate of claim 15, wherein the plurality of first electrostatic discharge circuits are arranged in an array, at least part of the first transfer connection electrodes and the second transfer connection electrodes are in an arc-shaped structure, the first electrostatic discharge circuits are electrically connected to one of the first data lines through an arc-shaped first transfer connection electrode or second transfer connection electrode, and the plurality of drive signal lines are provided in the third conductive layer;
wherein the first connection lines and at least part of the first signal lines are provided in the third conductive layer, and the plurality of data lines are provided in the fourth conductive layer; or, the first connection lines and at least part of the first signal lines are provided in the fourth conductive layer, and the plurality of data lines are provided in the third conductive layer.

17. The display substrate of claim 16, further comprising: a plurality of third power supply lines and a plurality of fourth power supply lines located in the bezel region; and a plurality of third power supply connection lines and a plurality of fourth power supply connection lines located in at least one corner region of the bezel region, wherein one ends of the plurality of third power supply connection lines are electrically connected to the plurality of third power supply lines respectively, and the other ends of the plurality of third power supply connection lines are electrically connected to the plurality of third electrostatic discharge circuits and the plurality of first electrostatic discharge circuits respectively; and one ends of the plurality of fourth power supply connection lines are electrically connected to the plurality of fourth power supply lines respectively, and the other ends of the plurality of fourth power supply connection lines are electrically connected to the plurality of third electrostatic discharge circuits and the plurality of first electrostatic discharge circuits respectively;
wherein the plurality of third electrostatic discharge circuits, the plurality of third power supply connection lines, and the plurality of fourth power supply connection lines are arranged in a stepped shape, and the third power supply connection lines and the fourth power supply connection lines are in a shape of a bending line extending in the first direction,
wherein the plurality of third power supply lines, the plurality of fourth power supply lines and the plurality of fourth power supply connection lines are provided in the third conductive layer, the plurality of third power supply connection lines comprise a first power supply connection structure and a plurality of second power supply connection structures, the first power supply connection structure is provided in the first conductive layer and electrically connected to one of the third power supply lines, at least part of the third electrostatic discharge circuits, and a plurality of first electrostatic discharge circuits in a first row; a second power supply connection structure comprises a first power supply connection substructure and a second power supply connection substructure, wherein the first power supply connection substructure is in a shape of a bending line and is provided in the first conductive layer, and is electrically connected to the plurality of third electrostatic discharge sub-circuits, the plurality of third power supply lines and the second power supply connection substructure, and wherein the second power supply connection substructure is provided in the third conductive layer and is electrically connected to the first power supply connection substructure and the plurality of first electrostatic discharge circuits.

18. (canceled)

19. The display substrate of claim 15, wherein the plurality of first electrostatic discharge circuits are arranged in a stepped shape, the bezel region further comprises a plurality of third transfer connection electrodes arranged in a stepped shape, wherein the plurality of first transfer connection electrodes and the plurality of second transfer connection electrodes are respectively electrically connected to the plurality of first electrostatic discharge circuits through the plurality of third transfer connection electrodes;
the plurality of third transfer connection electrodes are provided in the third conductive layer, the plurality of data lines are provided in the fourth conductive layer, and the plurality of first signal lines are provided in one or more layers from the first conductive layer to the third conductive layer.

20. The display substrate of claim 19, further comprising: a third power supply line and a fourth power supply line located in the bezel region; and a plurality of third power supply connection lines, a plurality of fourth power supply connection lines, a third power supply connection electrode and a fourth power supply connection electrode, which are located in at least one corner region of the bezel region;
wherein one ends of the plurality of third power supply connection lines are electrically connected to a plurality of third power supply lines respectively, and the other ends of the plurality of third power supply connection lines are electrically connected to the plurality of third electrostatic discharge circuits respectively; one of the third power supply connection lines is electrically connected to the third power supply connection electrode, and one of the fourth power supply connection lines is electrically connected to the fourth power supply connection electrode;
wherein the third power supply connection electrode is electrically connected to one of the third power supply connection lines and one ends of the plurality of first electrostatic discharge circuits, and the fourth power supply connection electrode is electrically connected to one of the fourth power supply connection lines and the other ends of the plurality of first electrostatic discharge circuits,
wherein the plurality of third electrostatic discharge circuits, the plurality of third power supply connection lines, and the plurality of fourth power supply connection lines are arranged in a stepped shape, the third power supply connection lines and the fourth power supply connection lines are in a structure of a bending line extending in the first direction, the third power supply connection electrode and the fourth power supply connection electrode are in a stepped blending line structure with extending directions being consistent with an extending direction of a corresponding corner region in the bezel region;
wherein the third power supply line, the fourth power supply line and the fourth power supply connection lines are provided in the third conductive layer, and the third power supply connection lines, the third power supply connection electrode and the fourth power supply connection electrode are provided in the first conductive layer.

21. (canceled)

22. A display device comprising the display substrate of claim 1, and light emitting elements disposed in the display region of the display substrate, wherein the light emitting elements are arranged in an array.
